(19) United States
(12) Patent Application Publication
(10) Pub. No.: US 2022/0035251 A1
(43) Pub. Date: Feb. 3, 2022

(54) METHODS TO FABRICATE 2D WEDGE AND LOCALIZED ENCAPSULATION FOR DIFFRACTIVE OPTICS

(71) Applicant: Applied Materials, Inc., Santa Clara, CA (US)

(72) Inventors: Jinrui GUO, Santa Clara, CA (US); Ludovic GODET, Sunnyvale, CA (US); Daihua ZHANG, Los Altos, CA (US); Kang LUO, Santa Clara, CA (US); Rami HOURANI, Santa Clara, CA (US)

(21) Appl. No.: 17/033,201

(22) Filed: Sep. 25, 2020

Related U.S. Application Data
(63) Continuation of application No. 63/059,826, filed on Jul. 31, 2020.
(60) Provisional application No. 63/081,961, filed on Sep. 23, 2020.

(51) Int. Cl. G03F 7/30; G02B 6/34

(52) U.S. Cl. CPC G03F 7/30; G02B 6/34

(57) ABSTRACT

A method of forming a three dimensional feature inwardly of a surface of a material includes providing a droplet dispenser including an outlet configured to dispense discrete droplets of a liquid material having a reactant therein capable of reacting with, and thereby removing, portions of the material layer with which the droplets come into contact, providing a support configured support the material thereon, the support, and the droplet dispenser, movable with respect to one another, such that the outlet of the droplet dispenser is positionable over different discrete areas of the surface of the material, and positioning the surface of the material under the droplet dispenser, and dispensing droplets to discrete portions of the surface of the material in a desired area thereof, to remove at least a portion of the material in the desired area and thereby form a three dimensional recess inwardly of the surface of the material.

### CROSS-REFERENCE TO RELATED APPLICATIONS

This application claims priority to U.S. Provisional Patent Application No. 63/059,826, filed Jul. 31, 2020 and U.S. Provisional Patent Application No. 63/081,961, filed Sep. 23, 2020, both of which are incorporated herein by reference in its entirety.

### BACKGROUND

### Field

The present disclosure generally relates to selective wet etching of multi-dimensional features inwardly of a material surface, more particularly to dispensing individual droplets of a material removal chemistry to discrete portions of a material surface to form multi-dimensional recess features therein in controlled, discrete, regions thereof.

### Description of the Related Art

Three dimensional features extending inwardly of a material layer surface are useful in a number of applications, for example for forming a 2D wedge in a surface of an optical device to create diffractive optics including for example waveguide combiners and flat optics, among other applications. In some case, these features are created in an optical device to allow incouplers, outcouplers, or both, to allow light to enter or leave an optical layer of the optical device. There is a need to more precisely locate these features, with a repeatable geometric profile, from device to device, using a wet removal chemistry, such as a wet etchant, without the need to process the substrate to form an etch mask thereon.

### SUMMARY

In one aspect, a method of forming a three dimensional feature inwardly of a surface of a material includes providing a droplet dispenser including an outlet configured to dispense discrete droplets of a liquid material having a reactant therein capable of reacting with, and thereby removing, portions of the material layer with which the droplets come into contact, providing a support configured support the material thereon, the support, and the droplet dispenser, movable with respect to one another, such that the outlet of the droplet dispenser is positionable over different discrete areas of the surface of the material, and positioning the surface of the material under the droplet dispenser, and dispensing droplets to discrete portions of the surface of the material in a desired area thereof, to remove at least a portion of the material in the desired area and thereby form a three dimensional recess inwardly of the surface of the material.

In another aspect, a method of forming a patterned photoresist on a material layer includes providing a droplet dispenser including an outlet configured to dispense discrete droplets of a liquid material therefrom, providing a support configured support the material layer thereon, the support, and the droplet dispenser, movable with respect to one another, such that the outlet of the droplet dispenser is positionable over different discrete areas of the surface of the material, providing a first liquid, dispensable from the droplet dispenser in droplet form, comprising a photoresist polymer, providing a second liquid, comprising a sensitizer which, when intermixed with the polymer, changes a reactivity of the polymer to electromagnetic energy, and positioning the surface of the material under the droplet dispenser, and dispensing droplets to discrete portions of the first liquid to the entire surface of the material layer, and dispensing droplets of the second liquid only on a desired, discrete area of the material layer to intermingle the first liquid and the second liquid in the desired, discrete area of the material layer.

### BRIEF DESCRIPTION OF THE DRAWINGS

FIG. 1A is a sectional view of an optical device with an optical layer and encapsulation layer.

FIG. 1B is a sectional view of an optical device with an optical layer and encapsulation layer with a 2D wedge formed therein.

FIG. 1C is an isometric view of the optical device of FIG. 1B having the optical layer and encapsulation layer with a 2D wedge formed therein.

FIG. 2 is a flowchart showing a method for manufacturing a 2D wedge on an optical device, for example the 2D wedge of FIGS. 1B and 1C.

FIG. 3A is a sectional view of an optical device with an optical layer thereon.

FIG. 3B is a sectional view of an optical device with an optical layer and a photoresist layer formed over the optical layer.

FIG. 3C is a sectional view of an optical device with an optical layer and photoresist layer with a 2D feature formed therein.

FIG. 4 is a flowchart showing a method for manufacturing the photoresist layer with a 2D feature formed therein of FIG. 3C.

FIG. 5A is a sectional view of an optical device with an optical layer and photoresist layer thereover.

FIG. 5B is a sectional view of an optical device with an optical layer and photoresist layer with a 2D wedge formed therein.

FIG. 5C is a sectional view of an optical device having the 2D wedge of FIG. 5B transferred into the optical layer thereof.

FIG. 5D is a sectional view of an optical device with an optical thereon.

FIG. 5E is a sectional view of the optical device of FIG. 5D, with the pattern of the 2D wedge transferred into the underlying optical layer.

FIG. 6A is a flowchart showing a method for manufacturing a 2D wedge in an optical device.

FIG. 6B is a flowchart showing a method for manufacturing a 2D wedge in an optical device.

FIG. 7A is a sectional view of an optical device with an optical layer and encapsulation layer.

FIG. 7B is a sectional view of an optical device with an optical layer and encapsulation layer with an opening formed through the encapsulation layer.

FIG. 8 is a flowchart showing a method for etching an opening in the encapsulation layer of the optical device of FIGS. 7A and 7B.

FIG. 9A is a sectional view of an optical device with an optical layer and encapsulation layer with a thickness abnormality in a film layer formed thereon.

FIG. 9B is a sectional view of an optical device with an optical layer and encapsulation layer having the abnormality thereon removed.

FIG. 10 is a flowchart showing a method for correcting an abnormality on a material layer of an optical device.

FIG. 11 is an isometric view of an inkjet etching device.

FIG. 12A is a schematic isometric view of a cleaning and drying station.

FIG. 12B is a sectional view of an optical device with an optical layer and encapsulation layer formed thereon.

FIG. 12C is a sectional view of an optical device with an optical layer and encapsulation layer having a 1D wedge thereon formed.

FIG. 12D is an isometric view of the optical device of FIG. 12C.

FIG. 13 is schematic representation of an inkjet dispenser.

FIG. 14 is a flowchart showing a method for etching a 1D wedge on a material layer of an optical device.

### DETAILED DESCRIPTION

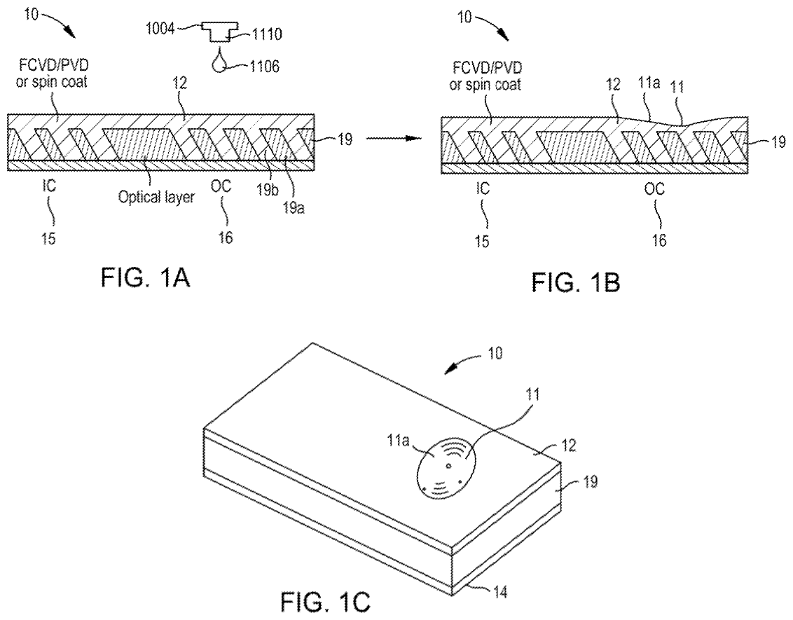

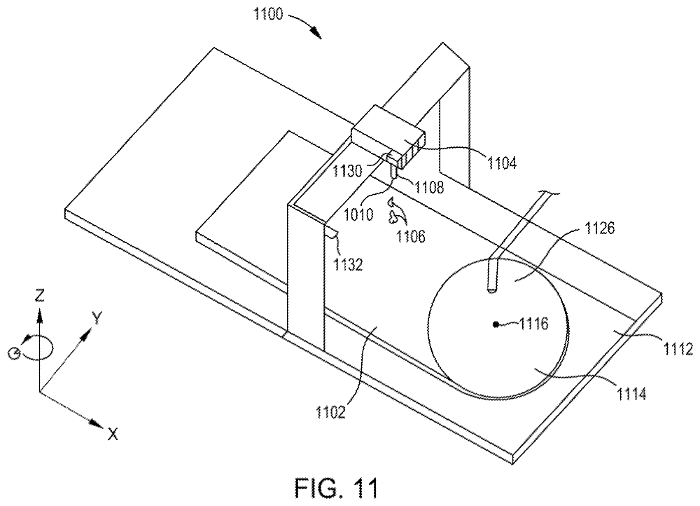

Referring initially to FIGS. 1A, 1B and 1C, schematic side sectional views and an isometric view of an optical device 10 with a 2D wedge 11 formed in the encapsulation layer thereof (FIGS. 1B, 1C) and useful as a waveguide for use in virtual reality imaging and other applications, is shown. An encapsulation layer 12 extends over and covers an optical layer 19 provided for purposes of receiving light through an incoupler 15 thereof, allowing that light to pass through the optical layer 19, and pass outwardly of the optical device through an outcoupler 16 thereof, all of which are integrally formed on a substrate 14. This optical device 10 includes a 2D wedge 11 in the encapsulation layer 12 in the region over the outcoupler 16, which here is formed using an inkjet wet etching device 1100 (FIG. 11) to dispense an etchant to selectively, locally, remove material from the encapsulation layer 12 of FIG. 1A to locally form the 2D wedge extending inwardly from the outer surface thereof over the outcoupler 16 as is shown in FIG. 1B. The 2D wedge 11 is formed in the encapsulation layer 12 by etching a wedge profile 11a, and leaving in place the wedge 11 as a variable thickness region of the encapsulation layer 12 in an area directly over the outcoupler 16, such that a relatively thick encapsulation layer 12 is present to cover the optical layer 19 to create conditions approximating total internal reflection at the interface of the optical layer 19 and the dielectric layer 12 in regions of the optical layer 19 between the incoupler 15 and the outcoupler 16, and modifying the transmissive properties and refractive properties of the device by forming the thinner conical feature of the 2D wedge 11 in, or as, a portion of the encapsulation layer 12 overlying the outcoupler 16.

To form a 2D wedge 11, the optical device 10 having a uniform thickness encapsulation layer 12 over an optical layer 19 supported on a substrate 14 thereof as shown in FIG. 1A is mounted to the moveable stage 1114 of an inkjet etching device 1100 of FIG. 11. As shown in FIG. 11, the inkjet etching device 1100 includes a table 1102 supported on, and moveable in the X direction with respect to, a base 1112 thereof, and at least one ink jet type dispenser 1104, here four such dispensers 1104a-d, each configured to dispense droplets 1106 of liquid material therefrom and each having an outlet nozzle 1108a-d terminating at a drop dispensing opening 1110a-d which faces the table 1102. The stage 1114 is rotationally coupled to the table 1102, such as through a shaft (not shown) connected to a stepper or servo motor (not shown) in the table 1102, and the stage 1114 is rotatable thereby about its center 1116 in the 0 direction of FIG. 11. To perform wet etching or removal of discrete portions of the encapsulation layer 12 to form the 2D wedge 11 in the desired region of the outwardly facing surface thereof, here over the outcoupler 16 of the device 10, stage 1114 is positioned below a drop dispensing opening 1110 of an outlet nozzle 1108 of an ink jet dispenser 1104 of the inkjet etching device 1100 with the encapsulation layer 12 facing the inkjet etching device outlet nozzle 1108, and the stage 1114 is rotated and moved in the X direction to position discrete portions or locations on the encapsulation layer 12 where the 2D wedge 11 is to be formed under the drop dispensing openings 1110 a-d of one or more of the inkjet dispensers 1104 a-d. The nozzle facing surface of the stage 1114 is located more than the thickness of an optical device 10 from the drop dispensing opening 1010 of the outlet nozzle 1008, leaving a distance between the drop dispensing opening 1110 and the surface of the encapsulation layer 12 of the optical device 10 on the order of, for example, 2 to 5 mm.

Here, the optical device 10, including the optical layer 19 with an incoupler 15 and outcoupler 16 encapsulated by an encapsulation layer 12, is positioned on the stage 1114 to form the 2D wedge 11 feature, here by etching a concave, generally conical, recess or wedge profile 11a into the surface of the encapsulation layer 12 by dispensing droplets 1106 of a wet etching or reactive chemistry onto the encapsulation layer 12 from one or more drop dispensing openings 1110 of the ink jet apparatus 1104 forming a conical outwardly facing surface of the 2D wedge 11. This wedge profile 11a which forms the outwardly facing surface of the 2D wedge 11 is established by causing greater etching to occur where the deepest point of the wedge profile 11a is to be formed, and incrementally less etching to occur on the flanking sides thereof, or where the wedge profile 11a is in the shape of a cone, incrementally less etching along the flanking portions radially outwardly from the deepest point of the wedge profile 11a to the edge of the wedge profile 11a. Examples of possible encapsulation layer 12 layer materials into which the 2D wedge profile 11a is to be formed, and their appropriately paired etchants include the following pairs; SiO2 material and DHF etchant, Si3N4 material and HF or H3PO4 etchant, TiO2 material and SC1 etchant, a Carbon based material and an organic solvent or a Photoresist remover etchant, and an aSI (amorphous silicon) material using KOH etchant. Etching of the 2D wedge profile 11a to form the 2D wedge 11 in a film layer such as the encapsulation layer 12 can be performed in a variety of different ways.

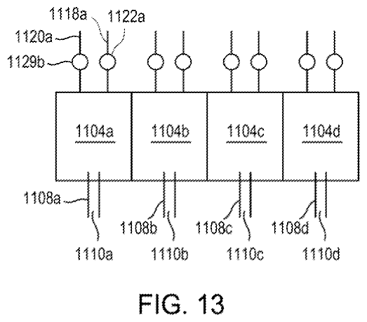

In one approach or aspect of forming the 2D wedge 11, droplets 1106 of etchant each having the same or nearly same etchant concentration or molarity is dropped in droplets 1106 from the injection nozzle 1108 in a uniform manner across the area where the 2D wedge 11 is to be formed. As the etchant reacts with the underlying thin film material, here the encapsulation layer 12 on which it was dropped, the etchant is consumed in a reaction with the thin film material. The reaction rate and consumption rate of the etchant are time related and the etching reaction can be altered or terminated by the addition of quench chemicals. In one aspect, as shown in FIG. 13, the ink jet dispenser 1104a providing etchant to the outlet nozzle 1108a thereof is connected to two different feed lines 1118a and 1120a. Here, first line 1118a contains an etchant of uniform concentration or molarity and a uniform concentration quenching chemical is provided in the second line 1120a. Each of the first and second lines 1118a, 1120a includes a valve 1122a, 1124a selectively opening, and capable of throttling or varying flow therethrough, the flow of the etchant (first line 1118a, valve 1122a) and quenching chemistry (line 1120a, valve 1124a) thence flowing into and through the drop dispensing opening 1110a of the outlet nozzle 1108a. The quenching chemical reacts with the etchant more preferentially than the etchant reacts with the encapsulation material 12, so that the etchant is consumed by the quenching chemical to stop the etching of the encapsulation layer 12.

To create a 2D wedge 11, i.e., etch the conical wedge profile 11a of FIGS. 1B and 1C using this ink jet printer 1100, etchant is released to the outlet nozzle 1108a through the first line 1118a to cover the entire area where the wedge profile 11a is to be formed, and the quenching chemistry is immediately thereafter released to the perimeter of the region where the wedge profile 11a profile is being formed. Sequentially deeper areas of the wedge profile 11a to be formed located inwardly of the perimeter of the wedge 11 to be formed will receive the quenching chemistry at sequentially later and later times at discrete time intervals between dispensing of the quenching chemistry such that the deepest point of the wedge 11 being formed receives the quenching chemistry last. The locations of the encapsulation layer 12 inwardly of the perimeter of the being-formed wedge profile 11a receive the quenching chemistry by movement of the stage 1114 to position discrete areas of the encapsulation layer 12 under the stream of droplets 1106 of the quenching chemistry at a pre-determined time at which the wedge 11, at that location, has the desired remaining encapsulation layer 12 thickness. Once the entire surface of the wedge profile 11a in the encapsulation layer 12 has been quenched, i.e., after a conical wedge profile 11a is formed inwardly of the surface thereof, it is then washed by deionized water, dispensed by rinse nozzle 1126 in FIG. 11, to remove etched debris, any remaining etchant, quenching chemical, and any byproduct formed therein. The optical device 10 with wedge formed therein is then removed from the stage 1114 and positioned in a cleaning and drying station 1128 having a spin rinse chuck 1130. Alternatively, instead of providing two feed lines 1118a, 1120a, inkjet dispenser 1104a may be used to dispense the etchant, and inkjet dispenser 1104b is used to dispense the quenching material. Further, to decrease the process time to etch the wedge profile 11a, two or more of the inkjet dispensers 1104a-c may be used to dispense one or both of the etchant and quenching chemistry, or at least two of the inkjet dispensers 1104a-d may be used to dispense etchant, and one or more different ones of the inkjet dispensers 1104a-d used to dispense the quenching chemistry.

In a second aspect, etchant is dispensed in a time or volume varied manner across the wedging area. As the dispensed etchant reacts with the underlying material, the etchant is consumed. To achieve deeper etching of the encapsulation layer 12, more droplets 1106 (increased density of droplets) are released in deeper etching areas, while fewer droplets 1106 (less droplet density) are released in the shallower regions of the to be formed wedge area, either at relatively the same time, or as etchant is depleted or consumed in the region where the deeper portions of the wedge profile 11a are to be formed as compared to shallower to be formed regions thereof. In this aspect, the droplets dispensed by the inkjet dispenser 1104 have a uniform etchant concentration. The etchant reacts with its location of contact with the encapsulation layer 12 until the chemical reaction thereof with the material of the encapsulation layer 12 is exhausted, i.e., until the etchant has been nearly consumed, leaving a limited amount of etching occurring per droplet 1106. Therefore, in areas with fewer droplets 1106 dispensed, at relatively the same time or over a period of time as etchant is consumed, less etching will occur inwardly of the encapsulation layer 12, whereas in areas of more droplet release at relatively the same time or over a period of time as etchant is consumed, more etching with occur inwardly of the encapsulation layer 12. Preferably, the etchant is released in a sequentially, planned, fashion over the surface of the encapsulation layer 12 using the X and Θ motions of the stage 1114 to drop droplets 1106 at locations where the wedge profile 11a is to be formed, at a rate no faster than the rate of consumption by the reaction thereof with the encapsulation layer material 12, wherein the stage 1114 moves the encapsulation layer 12 under the stream of droplets 1106 to selectively replenish the etchant at discrete locales on the encapsulation layer 12. The area of the encapsulation layer 12 receiving the droplets 1106 of etchant is step wise or continuously reduced, centered at the deepest point of the wedge profile 11a being formed inwardly of the encapsulation layer 12, as the etchant is consumed by reaction with the encapsulation layer 12 material, such that etchant is not dispensed to regions of the wedge profile 11a already formed that are shallower than a certain depth, i.e., the regions where the final depth of the wedge profile 11a has already been reached by the etching. The stage 1114 initially moves the encapsulation layer 12 under the drop dispensing opening 1110 of the outlet nozzle 1108 to cover the full area where the of the wedge profile 11a which defines the outer surfaces of the wedge 11 is to be formed, and then sequentially smaller and smaller areas centered at the deepest locale of the of the wedge profile 11a, and the stage eventually stops to position the deepest location of the to be formed wedge profile 11a under the last of the droplets 1106 being discharged from the drop dispensing opening 1110 of the outlet nozzle 1108, to complete etching of the encapsulation layer 12 to form the wedge profile 11a and thus the wedge 11 in the encapsulation layer 12. By this methodology, the portions of the encapsulation layer 12 where the shallower flanks of the wedge profile 11a being formed will receive, and be etched by, fewer droplets 1106 of etchant, whereas the portions of the deepest areas of the wedge profile 11a being etched into the encapsulation layer 12 receive the most droplets 1106, and there the encapsulation layer 12 is recessed inwardly the deepest. The surface of the encapsulation layer 12, including of the just formed wedge 11 outer surface, is then washed by deionized water, dispensed by wash nozzle 1126 to remove etched debris, etchant, quenching chemical, and any byproduct formed therein. Then, the optical device 10 is removed from the support 1114 and positioned in a cleaning and drying station 1128. As with the first aspect of forming the wedge profile 11a, multiple ones of the inkjet dispenser's 1104a-b may be used to discharge droplets, and thereby potentially reduce the time required to etch the wedge profile 11a.

In a third aspect, etchant to form the wedge profile 11a is released in a varied concentration or molarity across the area where the wedge profile 11a to define the wedge 11 in the encapsulation layer 12 is to be formed. As the etchant reacts with the underlying material of the encapsulation layer 12, the etchant is consumed. To achieve deeper etching in desired regions of the encapsulation layer 12, droplets 1106 having a higher etchant concentration or molarity are released in areas to be deeply etched, while less concentrated droplets (diluted droplets) are released in the areas to be etched less, i.e., the shallower areas of the wedge profile 11a. To achieve this, in one aspect the dispenser 1104 providing etchant to the outlet nozzle 1108a is connected to two different feed lines 1118a and 1120a. First line 1118a contains an etchant of uniform concentration or molarity and a dilutant, for example deionized water, and is provided in second line 1120a. Each of the first and second lines 1118a, 1120a includes a valve 1122a, 1124a selectively opening, and capable of throttling or variable flow therethrough, the flow of the etchant (line 1118a, valve 1122a) and dilutant (line 1120a, valve 1124a) thence flowing into and through the outlet nozzle 1108a. The relative flows of the dilutant and the etchant result in different concentrations of etchant per droplet 1106 dispensed from the drop dispensing opening 1110a. The dispensed etchant 1116 reacts with its location of contact with the encapsulation layer 12 until the chemical reaction is exhausted, leaving a limited amount of etching occurring per droplet, with less etching happening where droplets 1106 having lower etchant concentration were dispensed. Etchant droplets 1106 are released in a sequential fashion at a rate no quicker than the rate of consumption thereof by reaction with the encapsulation layer material 12, wherein the stage 1114 moves and passes the wedge profile 11a forming region of the optical device 10 under the inkjet stream 1106. The portion of the area where the wedge profile 11a is to be formed and onto which the etchant is dispensed extends over the full area where the wedge profile 11a is to be formed, with the drop dispensing opening 1110a of the outlet nozzle 1108a releasing droplets 1106 having increasing larger ratios of etchant to dilutant from the location of the perimeter of the area of the encapsulation layer 12 to be etched to the location on the encapsulation layer 12 where the deepest etching into the encapsulation layer 12 to form the wedge profile 11a is to occur, at which locale no dilutant will be released with the etchant. Thus, the less deep flanks of the wedge profile 11a will receive less concentrated etchant droplets whereas the deepest areas of the encapsulation layer 12 where the wedge profile 11a is being formed receive the most concentrated of etchant droplets 1106, and the wedge profile 11a is there etched the deepest. The surface of the encapsulation layer 12 and formed wedge 11 is then washed by deionized water, dispensed by rinse nozzle 1126, to remove etched debris, etchant, quenching chemical, and any byproduct formed therein. Then, the optical device 10 is removed from the support 1114 and positioned in a cleaning and drying station 1128. As with the first and second aspects, multiple ones of the inkjet dispensers 1104a-b may be used to discharge droplets of different concentration, and thereby potentially reduce the time required to etch the wedge profile 11a. Additionally, one or more of the inkjet dispensers 1104a-d may be supplied with the etchant, including etchant of different concentrations, wherein lower concentration droplets 1106 are dispensed to regions of the surface of the encapsulation layer 12 where the variable depth opening is to be shallower, and greater concentration etchant dispensed to regions of the surface of the encapsulation layer 12 where the variable depth opening is to be deeper. In this approach, one of the inkjet dispensers 104a-d can dispense a dilutant, which is then mixed with the etchant of different concentrations on different regions of the encapsulation layer, to provide a continuous of nearly continuous change in etchant concentration in the liquid on the encapsulation layer from the areas of the deepest to shallowest portions of the wedge profile 11a being formed.

In a fourth aspect, etchant is released in different size droplets 1106 across the area of the encapsulation layer where the wedge profile 11a to form the wedge 11 is to be formed. As the etchant reacts with the underlying material of the encapsulation layer 12, the etchant is consumed. To achieve deeper etching into the encapsulation layer, larger droplets 1106 are released in deep etching areas, while smaller droplets 1106 are released in the less deep wedge profile 11a areas. To achieve this, the inkjet printer 1100 includes an inkjet dispenser 1104 capable of dispensing smaller or larger droplets to be dropped as droplets 1106 dropped through the droplet dispensing opening 1110 of the outlet nozzle 1108. The etchant reacts with its location of contact with the encapsulation layer 12 until the chemical reaction is exhausted, leaving a limited amount of etching occurring per droplet, with less etching happening where smaller droplets 1106 were dispensed. Here, the viscosity of the droplets is increased to prevent significant movement thereof from their location of placement on the encapsulation layer 12. Etchant droplets 1106 are released over the entire region of the encapsulation layer 12 where the wedge profile 11a to form the wedge 11 is to be formed, in a sequential fashion at a rate no quicker than the rate of consumption of the etchant by the reaction thereof with the encapsulation layer material 12, wherein the stage 1114 moves the encapsulation layer 12, and thus different portions of the wedge profile 11a being formed to different depths of the optical device 10 thereon under the stream of droplets 1106. The size of the droplets 1106 is sequentially increased from the perimeter, to the deepest etched location, of the wedge profile 11a to be formed. Thus, the shallower flank areas of the wedge profile 11a being formed will receive smaller etchant droplets 1106 whereas the deepest areas of the wedge profile 11a being formed receive the largest droplets, and the encapsulation layer 12 is therefore etched the deepest at that location. The surface of the encapsulation layer 12 with the wedge 11 formed therein is then washed by deionized water, dispensed by wash nozzle 1126 to remove etched debris, etchant, quenching chemical, and any byproduct formed therein. Then, the optical device 10 will be removed from the support 1114 and positioned in a cleaning and drying station 1128.

As with the first to third aspects of forming the wedge 11, multiple ones of the inkjet dispensers 1104a-b may be used to discharge droplets of different sizes, or each inkjet dispenser 1104 a-d of the inkjet dispensers 1104a-d is configured to provide droplets within a different subrange of sizes, and thereby potentially reduce the time required to etch the wedge profile 11a.

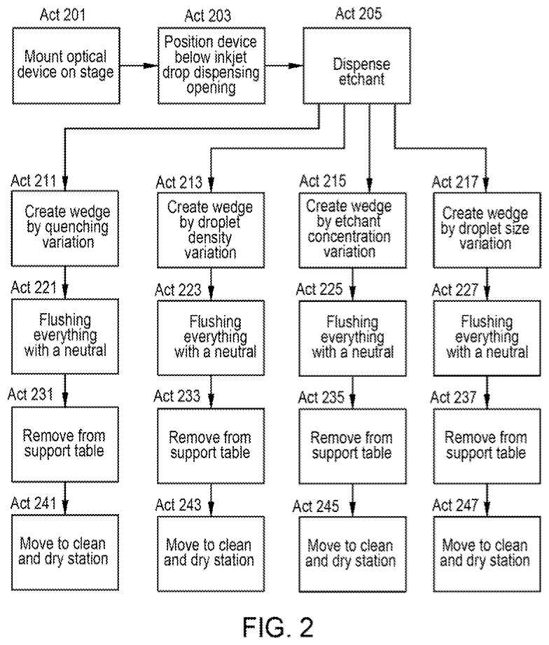

FIG. 2 is a flowchart showing a series of activities for creating a 2D wedge 11 in an encapsulation layer 12 of an optical device 10 according to the sequence of processes described with respect to FIG. 1. Initially, an optical layer 19 is prepared. However, the encapsulation layer 12 may need to be of varied thickness to create a desired effect for the optical device 10, thus the forming of a 2D wedge 11 can be performed. Herein, the process sequence for forming of the 2D wedge in the encapsulation layer 12, is described.

At Act 201 the optical device 10 is mounted on the stage 1114 and at Act 203 it is positioned by the stage 1114 within the inkjet wet etching device 1100, by movement in the X and Θ directions of FIG. 11, to position the desired locale on the encapsulation layer 12 where the 2D wedge is to be formed below drop dispensing opening 1110 of an outlet nozzle 1108 of an ink jet dispenser 1104. At Act 205 an etchant capable of reacting with (etching) the material of the encapsulation layer 12 is released from the drop dispensing opening as droplets 1106. Preferably, this etchant has an etch rate of the material of the optical layer 19 on the order of more than 100 times less than the etch rate for the encapsulation layer 12 when exposed to that same etchant.

In one aspect, after etchant is released to the outlet nozzle 1108a through line 1118a to cover the entire area where the wedge profile 11a to form the wedge 11 is to be formed, a quenching chemistry is immediately thereafter released to the perimeter of the region where the wedge profile 11a is being formed in Act 211. The locations of the encapsulation layer 12 inwardly of the perimeter of the being-formed wedge profile 11a receive the quenching chemistry by movement of the stage 1114 to position discrete areas of the encapsulation layer 12 under the stream of drops 1106 of the quenching chemistry at a pre-determined time at which the wedge profile 11a, at that location, has removed sufficient material to form the desired encapsulation layer 12 thickness of the wedge 11 thereat, followed by deeper and deeper areas of the wedge profile 11a being formed. Once the entire surface of the wedge profile 11a region of the encapsulation layer 12 has been quenched, at Act 221 the surface is then washed by deionized water, dispensed by rinse nozzle 1126, to remove etched debris, any remaining etchant, quenching chemical, and any byproduct formed therein. At Act 231 the optical device 10 with the wedge 11 formed therein is then removed from the stage 1114 and positioned in a cleaning and drying station 1128 having a spin rinse chuck 1130 at Act 241 to further rinse, and then dry, the surface of the encapsulation layer 12 with the 2D wedge formed therein.

In a second aspect, deeper etching is achieved by dispensing more droplets (increased density of droplets) in areas of the wedge profile 11a to be formed deeper into the encapsulation layer 12, while fewer droplets (less droplet density) are released in the shallower regions of the wedge profile 11a to be formed in act 205. Here, the inkjet dispenser 1104 drops droplets 1106 having a uniform etchant concentration to contact the region of the encapsulation layer 12 where the wedge profile 11a is to be formed until the chemical reaction is exhausted, i.e., until the etchant has been nearly consumed, leaving a limited amount of etching occurring per droplet. Thereafter, in Act 213, by movement of the stage 1114 and consequently the encapsulation layer 12 under the stream of droplets 1106, etchant is selectively replenished at discrete locales on the encapsulation layer 12 here the wedge profile 11a is being formed, to further the encapsulation layer 12 in Act 213, over time, whereby a density variation of droplets over the surface of the region where the wedge profile 11a is being formed is achieved. Alternatively, where the droplets 1106 have a relatively high viscosity so as not to significantly move from their location of being dropped on the encapsulation, more droplets 1106 can be dropped in deeper locations of the wedge profile 11a to be formed than at shallower regions thereof in a single pass of the wedge profile 11a forming region of the encapsulation layer 12 under the drop dispensing outlet 1010, so that a thicker layer of etchant is present over the deeper locations of the wedge profile 11a to be formed than at shallower regions thereof. In Act 223 the surface of the encapsulation layer 12 including the wedge 11 is then washed by deionized water, dispensed by wash nozzle 1126 to remove etched debris, etchant, quenching chemical, and any byproduct formed therein. From here, the optical device 10 will be removed from the support 1114 in act 233 and positioned in a cleaning and drying station 1128 in Act 243 to further rinse, and then dry, the surface of the encapsulation layer 12 with the 2D wedge formed therein.

In the third aspect, in Act 205 the etchant is released in droplets 1106 of different etchant concentration at different locations of the wedge profile 11a being formed. In Act 215, droplets having a higher etchant concentration or molarity are released in areas of the encapsulation layer 12 to be deeply etched, while less concentrated droplets (diluted droplets) are released in the areas to be etched less, i.e., the shallower locations of the wedge profile 11a to be formed. The surface of the encapsulation layer 12 including the wedge 11 is then washed by deionized water in Act 225, dispensed by rinse nozzle 1126, to remove etched debris, etchant, quenching chemical, and any byproduct formed therein. From here, the optical device 10 will be removed in Act 235 from the support 1114 and positioned in a cleaning and drying station 1128 in Act 245 to further rinse, and then dry, the surface of the encapsulation layer 12 with the 2D wedge formed therein.

In a fourth aspect, as the etchant released in Act 205, they are released in different size droplets across the area of the encapsulation layer 12 where the wedge profile 11a is to be formed. In Act 217, larger droplets are released in deeper etching areas, while smaller droplets are released in the less deep etching areas, the droplet size modulated by the inkjet dispenser 1104. The shallower flanks of the wedge profile 11a being formed will receive smaller etchant droplets 1106 whereas the deepest areas of the wedge profile 11a being formed receive the largest droplets, and the encapsulation layer 12 is therefore etched the deepest at that location. In act 227 the surface of the encapsulation layer 12 with the wedge 11 formed therein is then washed by deionized water, dispensed by wash nozzle 1126 to remove etched debris, etchant, quenching chemical, and any byproduct formed therein. In Act 237, the optical device 10 will be removed from the support 1114 and positioned in a cleaning and drying station 1128 in Act 247 to further rinse, and then dry, the surface of the encapsulation layer 12 with the 2D wedge formed therein.

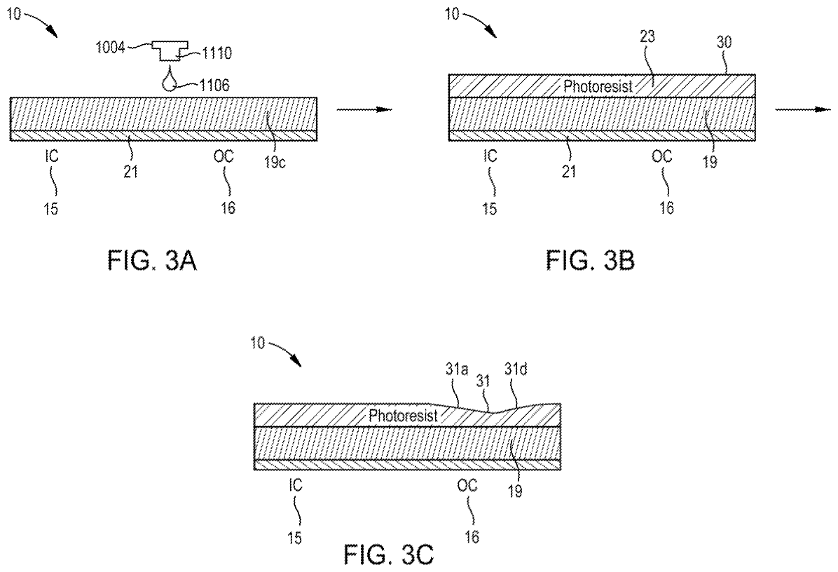

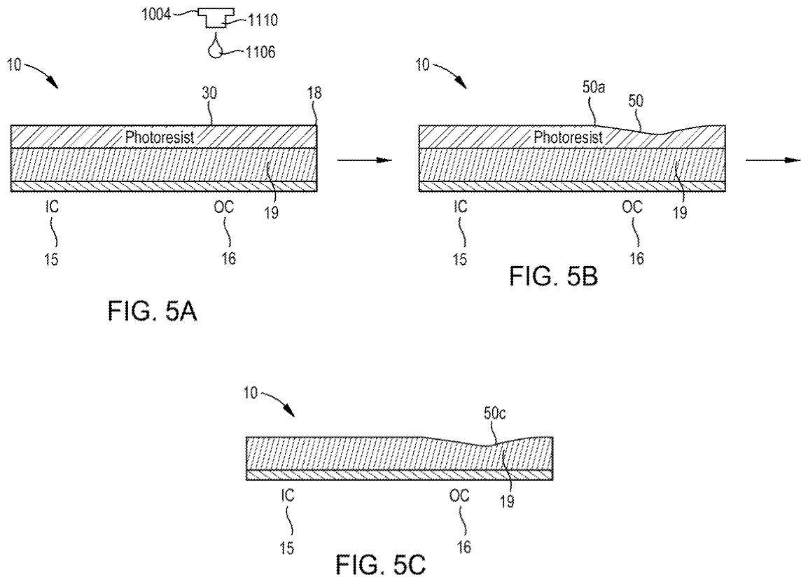

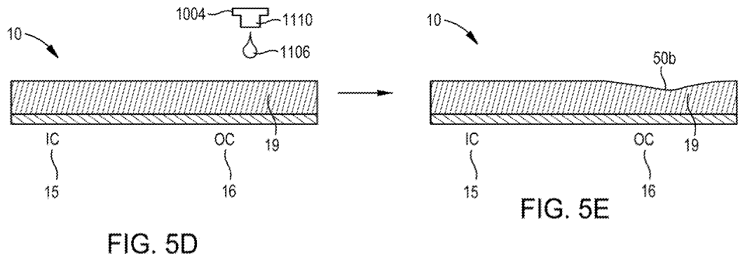

Referring now to FIGS. 3A to 3C, an additional methodology for forming a photoresist layer for forming a wedge profile, such as that in the optical layer of FIG. 5E, is shown. Here, the inkjet printer 1100 is used to deposit individual droplets 1106 of a photoresist material to form a photoresist layer 30 on a thin film layer 19c present on an underlying substrate 21, wherein the formed photoresist layer 30 includes a varying composition over the span thereof, such that a discrete non-uniform portion 23 is formed in the photoresist layer 30 such that the photoresist layer 30, after being exposed to an electromagnetic energy source such as UV or other source and developed, has a three dimensional feature 31 formed inwardly of the layer of photoresist 30. Thereafter, by anisotropic etching such as in a plasma etch chamber, the three dimensional profile of the three dimensional recess in the photoresist 30 is transferred into the underlying thin film layer 19c, forming a structure similar to the 2D wedge in FIG. 5E.

The photoresist material to form the photoresist layer 30 is dispensed in liquid form which is then baked to harden it, for example by including a heater (not shown) under and thermally connected to the stage 1114 of the ink jet apparatus 1100. Here, the composition of the photoresist layer 30 is changed within to non-uniform region 23 as compared to the remainder of the photoresist of the photoresist layer 30 formed on the thin film layer 19c, and is used to form the three dimensional feature 31 in the photoresist layer 30 after it has been exposed to electromagnetic radiation and developed. The composition of the photoresist 30 in the portion of the photoresist 30 deposited in the non-uniform region 23 is also varied across the span or width of the non-uniform region 23. For example, the polymer, solvent and non-sensitizer additive components of the photoresist material which is dispensed as droplets 1106 by the ink jet apparatus 1100 can remain uniform across the length, width and depth of the photoresist layer formed on the thin film layer 19c, but the sensitizer portion of the photoresist, which causes the polymer of the photoresist material to change properties when exposed to the proper electromagnetic energy such as UV light, is non-uniformly included in the photoresist layer 30, both as between the non-uniform region 23 and the remainder of the photoresist layer 30, and within the non-uniform region 23 of the photoresist layer 30.

To form this non-uniform region, first line 1118a of the inkjet dispenser 1104a is configured to supply the polymer, solvent and non-sensitizer additive components of the photoresist material, and second line 1120a of the inkjet dispenser 1104a is configured to supply the sensitizer to the inkjet dispenser 1104 and hence to the outlet nozzle 1108a. With the substrate 1102 secured to the stage 1114, the stage 1114 is moved rotationally about the axis 1116 thereof, and in the X direction using the table 1102 movement, to locate all areas of the upper surface thin film layer 19c to face the outlet drop dispensing opening 1010 of the dispense nozzle 1108 to receive the polymer, solvent and non-sensitizer additive components of the photoresist thereon. When the drop dispensing opening 1110 of the outlet nozzle 1108 is facing a portion of the thin film 19c over which the non-uniform region 23 is to be formed, valve 1124a is also opened to simultaneously flow polymer, solvent and non-sensitizer additive components of the photoresist, along with the sensitizer, onto the thin film layer 19c.

Assuming, for example, that the three dimensional feature 31 is circular in plan view, and has a conical profile extending from the edge 31a to the deepest portion 31b thereof and similar to the wedge profile 11a and 2D wedge 11 shown in FIGS. 1B and 1C, with a smooth depth transition from the edge 31a to the deepest portion 31b thereof. When the surface of the thin film layer 19c directly under the drop dispensing opening 1110 is an area where the three dimensional feature 31 is not to be formed, only the polymer, solvent and non-sensitizer additive components of the photoresist are dispensed as droplets 1106. As the substrate 21 is positioned under the drop dispensing opening 1110 of the outlet nozzle 1108 and the substrate 19c is moved to first position the location of the edge 31a of the to be formed three dimensional feature 31 directly below the drop dispensing opening 1110, sensitizer is added to the polymer, solvent and non-sensitizer additive components of the photoresist material being dispensed as droplets 1106 from the drop dispensing opening 1110. As the stage 1014 moves the substrate 21 to position the deepest portion 31b of the to be formed three dimensional feature 31 below the drop dispensing outlet 1110, more sensitizer is continuously added to the polymer, solvent and non-sensitizer additive components of the photoresist material being dispensed as drops 1106 through the drop dispensing opening 1110a, such that the greatest concentration of sensitizer in the mixture of polymer, solvent and non-sensitizer additive and sensitizer of the photoresist being dispensed is present at the deepest location of the three dimensional recess 1214 to be formed, and this concentration is gradually, here generally linearly, reduced as the stage 1114 causes the location of the thin film layer below the opening 1110 to traverse from the deepest 31b, to the shallowest (occurring at the edge 31a) location of the three dimensional feature 31 to be formed. The resulting photoresist layer 30, which is electromagnetic energy sensitive only in the region thereof where the sensitizer is present, may be formed in a single pass of all surfaces of the thin film layer 19c under the outlet nozzle 1108, or multiple layers of polymer, solvent and non-sensitizer additive components of the photoresist, and where location appropriate (where the three dimensional feature is to be formed) a gradient of sensitizer, can be dispensed to form the photoresist layer 30. Here, for example, as the substrate 21 is moved from the deepest portion 31d of the non-uniform region 23 of the photoresist layer 30 being formed toward the shallow perimeter 31a portion thereof, initially, only at the deepest portion 31d is the sensitizer added. Thence, in successive passes of forming the non-uniform region 23 of the photoresist layer 30, the area extending from the deepest portion 31d to the edge 31a is successively increased, until in the final pass of droplets 1106 being dispensed, the sensitizer is dispensed over the entire area where the non-uniform portion 23 is formed. Additionally, the photoresist layer 30 can be formed by flowing only the polymer, solvent and non-sensitizer additive components of the photoresist through the inkjet dispenser 1104a, and the sensitizer flowed through the adjacent ink jet dispenser 1104b. As a result, a photoresist layer having a localized electromagnetic energy sensitive region therein, that localized electromagnetic energy sensitive region having a gradient of sensitivity to electromagnetic energy causing a change in the structure thereof, is formed.

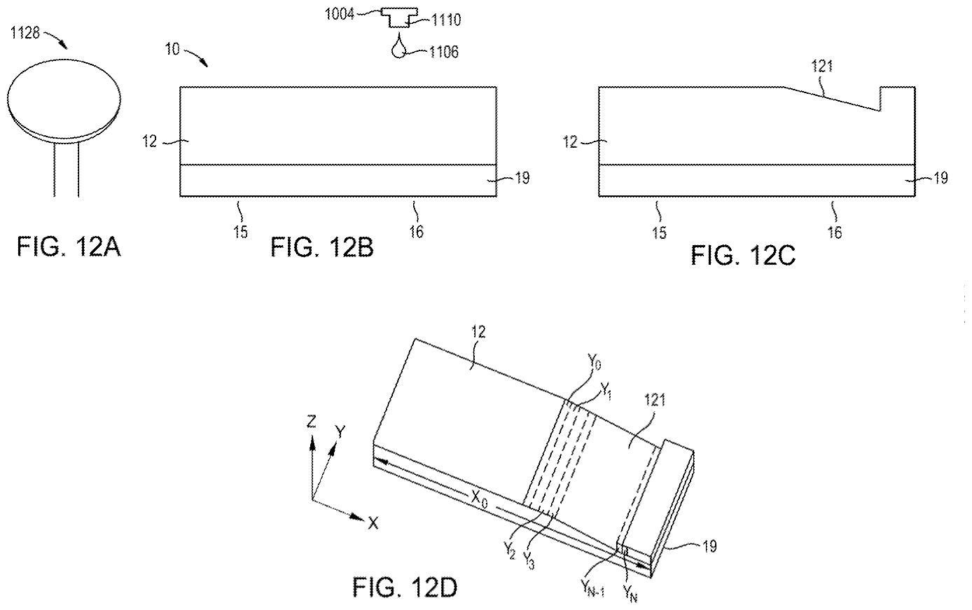

After the photoresist layer 30, having the varying concentration of sensitizer region formed therein to form the non-uniform region 23, is exposed to electromagnetic radiation to which the polymer and sensitizer combination is sensitive, the material properties of the varying sensitizer concentration region are changed so that more of the polymer in the deepest to be formed region of the non-region 23 undergoes a change in property making it more susceptible to being etched, and this increase in etchability is reduced relatively to zero at the edge 31a of the to be formed three dimension feature 31. The substrate 23 with the exposed photoresist layer is then exposed to a developer, and reacted polymer is dissolved and washed away to yield the three dimensional feature 31 in the photoresist 30 structure of FIG. 12D.

Alternatively, where the sensitizer causes the polymer, when exposed to the electromagnetic energy, to be more resistant to being dissolved by the developer, the above described sequence is reversed, and the regions of the photoresist layer being formed where the three dimensional feature 31 will not be present receives the sensitizer, and as the edge 31a of the to be formed three dimensional feature 31 becomes present under the drop dispensing opening 1110, the amount of sensitizer is reduced, such that the closer to the deepest part 31b of the two be formed three dimensional feature 31, the less sensitizer is present, and the lowest concentration, as little as zero, sensitizer is present at the location of the deepest portion 31b of the to be formed three dimensional feature 31.

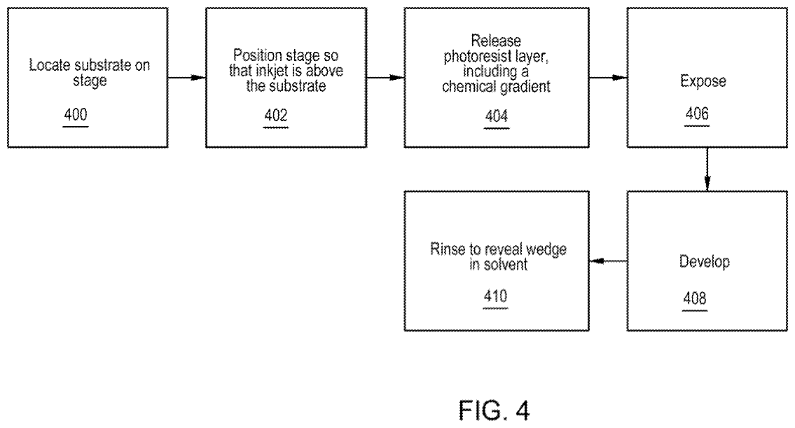

Referring to FIG. 4, a process sequence for forming the three dimensional feature 31 is shown in process flow format. First, at Act 400, a substrate 23 having the thin film layer 19c which may be, for example, an encapsulation layer 12 formed over an optical layer 19 as shown in FIG. 1, is mounted to the stage 1114 of an inkjet printer 1100. Then, in Act 402, the stage is moved to position the thin film layer 19c under the droplet dispensing opening 1110 of an inkjet dispenser 1104. Then while moving the stage in the X and Θ directions, droplets of the photoresist components are released from the droplet dispensing opening 1110 onto the thin film layer 19c, such that a gradient in sensitizer is present within the region of the photoresist layer 30 being formed a concave feature is to be formed, in Act 404. After the full thickness of the photoresist layer is deposited and baked, and in Act the 406 the photoresist is exposed to electromagnetic radiation capable of changing the material properties of the polymer in the photoresist where the sanitizer either is, or is not present, and in Act 408 the exposed photoresist layer 30 is developed. Then, in Act 410, the developed photoresist layer 30 is rinsed with a solvent which dissolves the polymer and photoresist having the sanitizer (or not having the sanitizer) to form the three dimensional feature 31 inwardly of the layer of photoresist 30.

In FIGS. 5A through 5C, a schematic side view of the results of a series of processes actions used to create an optical device 10 with a depression 50a extending inwardly of the optical layer 19 of the optical device 10, useful as a waveguide for use in virtual reality imaging and other applications, are shown. In contrast to the method of forming the feature 31 of FIGS. 3 and 4, where a photoresist layer 30 is formed which includes integrally therein a region having varying photoresist material properties, here the full thickness of a photoresist layer 30 is formed to cover an optical layer 19 and it has continuous material properties across the entire surface thereof. This optical device 10 provided with the photoresist layer 30, is then exposed to anisotropic etching conditions to transfer a recess or depression 50a in the photoresist layer into the underlying optical layer 19 in one strategy as seen in FIGS. 5A to 5C and without a photoresist layer in another strategy, as seen in FIGS. 5D and 5E where the recess, or depression 50b, is formed directly in the optical layer 19 by local inkjet etching thereof. A relatively thick photoresist layer 30 can be used to cover the optical layer 19 of FIG. 5A to create conditions allowing for a photoresist wedge 50 shown in FIG. 5B, fabricated by forming the depression 50a inwardly of the photoresist 30 of FIG. 5A, such that the photoresist layer 30 of FIG. 5B is to be used as a mask for etching the optical layer 19 and transferring the wedge 50 of FIG. 5B into the optical layer 19 of FIG. 5C as a transferred optical layer wedge 50c.

To form a 2D photoresist wedge 50 as a portion of the photoresist layer 30, the optical device 10 having a uniform thickness photoresist layer 30 as shown in FIG. 5A is mounted to the moveable stage 1114 of an inkjet printer 1100 of FIG. 11. The printer 1100 here serves as a local, to the photoresist layer 30 surface of the device 10, dispenser of an etchant or reactant capable of removing or etching away discrete portions of the material of the photoresist layer 30. The printer includes a table 1102 supported on, and moveable in the X direction with respect to, a base 1112 thereof, and at least one ink jet type dispenser 1104, here four such dispensers 1104a-d, each configured to dispense droplets 1106 of liquid material therefrom, and each having an outlet nozzle 1108 which selectively faces the table 1102. The stage 1114 is rotationally coupled to the table 1102, such as through a shaft (not shown) connected to a stepper motor (not shown) in the table 1112, and the stage 114 is rotatable about its center 1116 in the 0 direction of FIG. 11. To perform etching of the photoresist layer 31 to form the 2D photoresist wedge 50, here having a topography similar to the conical 2D wedge 11 of FIGS. 1B and 1C, in the desired region thereof, stage 1114 is positioned below the outlet 1108 of the ink jet dispenser 1104 of the inkjet etching device 1100 with the photoresist layer 30 side of the device 10 facing the drop dispensing outlet 1110 of the outlet nozzle 1108, and the stage 1114 is rotated and moved in the X direction to position discrete portions of the location on the device 10 where the 2D photoresist wedge 50 is to be formed under the drop dispensing outlet 1100 of an outlet 1108 of one or more inkjet dispensers 1104a-d. The nozzle facing surface of the stage 1114 is located more than the thickness of an optical device 10 from the drop dispensing opening 1010 of the outlet nozzle 1008 exit of the inkjet nozzle, leaving a distance between the nozzle exit and the surface of the photoresist layer 30 of the optical device 10 on the order of 2 to 5 mm.

Here, the optical device 10, covered by a photoresist layer 30, is positioned on the stage 1114 to form the 2D photoresist wedge 50 into the extant photoresist layer 30 of FIG. 5A by etching a depression 50a inwardly of the outer surface of the photoresist layer 30, by dispensing droplets 1106 of a wet etching or reactive chemistry onto the photoresist layer 30 from one or more outlets 1108 of an ink jet dispenser 1104, the resulting depression 50a shown in FIG. 5B. The profile of the depression is established by causing greater etching to occur where the deepest point of the depression 50a is to be formed, and incrementally causing less etching to occur on the flanking sides extending from the deepest portion of the to be formed depression 50a, or where a circular region, flanking portions extending radially outwardly from the deepest point of the depression 50a to be formed. An example of the material of the photoresist layer 30 layer its appropriately paired etchants include a Carbon based material and an organic solvent or a photoresist remover etchant. Etching of the depression 50a into the photoresist layer 30 can be performed in a variety of different ways.

In one approach or aspect of forming the depression 50a, etchant having the same etchant concentration or molarity is dropped in droplets 1106 from the injection nozzle 1108 in a uniform manner across the area where the depression 50a to form the photoresist wedge 50 is to be formed. As the etchant reacts with the underlying photoresist 30 on which it was dropped, the etchant is consumed in a reaction with the photoresist 30. The reaction rate and consumption rate of the etchant are time functions and the total amount of photoresist locally etched away can be altered by the addition of quench chemicals. In one aspect, as shown in FIG. 13, the inkjet dispenser 1104a providing etchant to the outlet nozzle 1108a is connected to two different feed lines 1118a and 1120a. First line 1118a contains an etchant of uniform concentration or molarity and a uniform concentration quenching chemical is provided in second line 1120a. Each of the first and second lines 1118a, 1120a includes a valve 1122a, 1124a selectively opening, and capable of throttling or varying flow therethrough, the flow of the etchant (line 1118a, valve 1122a) and quenching chemistry (line 1120a, valve 1124a) then flowing into and through the drop dispensing outlet 1110a of the outlet nozzle 1108a. The quenching chemical reacts with the etchant more preferentially than the etchant reacts with the photoresist layer 30, so that the etchant is consumed by the quenching chemical to stop the etching of the photoresist layer 30.

To create a photoresist wedge 50 using this system, etchant is released to the outlet nozzle 1108a through line 1118a to cover the entire area where the photoresist wedge 50 is to be formed, and the quenching chemistry is immediately thereafter released to the location of the perimeter of the depression 50a is being formed. Sequentially deeper areas of the depression 50 to be formed located inwardly of the perimeter of the depression 50 to be formed will receive the quenching chemistry at sequentially later and later times at discrete time intervals between the dispensing of the quenching chemistry until the deepest point of the depression 50a being formed receives the quenching chemistry. The locations of the photoresist layer 30 inwardly of the perimeter of the being-formed depression 50a receive the quenching chemistry by movement of the stage 1114 to position discrete areas of the photoresist layer 30 under the stream of droplets 1106 of the quenching chemistry at a pre-determined time based on the desired depth of the depression 50a at that location, such that the desired photoresist layer 30 thickness to provide the photoresist wedge 50 remains. Once the entire surface of the depression 50 of the photoresist layer 30 has been quenched, the photoresist 50 surface is then washed with a neutral liquid such as deionized water, dispensed by rinse nozzle 1126, to remove etched debris, any remaining etchant, quenching chemical, and any byproduct formed therein. The optical device 10 with the photoresist wedge 50 formed therein is then removed from the stage 1114 and positioned in a cleaning and drying station 1128 having a spin rinse chuck 1130 to be further cleaned and dried.

In a second aspect of fabricating the photoresist wedge 50, etchant is dispensed in a time varied manner across the area where the depression 50a is to be formed. As the dispensed etchant reacts with the underlying material, the etchant is consumed. To achieve deeper etching of the photoresist layer 30 in selected portions thereof, more droplets 1106 (increased density of droplets) are released in deeper etching areas, while fewer droplets (less droplet density) are released in the shallower regions where the depression 50a is to be formed. In this aspect, the inkjet dispenser 1104 droplets 1106 have a uniform etchant concentration. The etchant reacts with the photoresist at its location of contact with the photoresist layer 30 until the chemical reaction is exhausted, i.e., until the etchant has been nearly consumed, leaving a limited amount of etching occurring per droplet. Therefore, in areas with fewer droplets, less etching will occur inwardly of the photoresist layer 30, whereas in areas of more droplet release, more etching with occur inwardly of the photoresist layer 30. Etchant is released in a sequentially planned fashion at a rate no faster than the rate of consumption by the reaction thereof by reaction with the photoresist layer 30, wherein the stage 1114 moves the photoresist layer 30 under the stream of droplets 1106 to selectively replenish the etchant at discrete locales on the photoresist layer 30, with more droplets 1106 dispensed in regions where the depression 50a is to be formed deeper into the photoresist 30, and fewer droplets dispensed in regions where the depression 50a is to be formed shallower into the photoresist 30, with the greatest number of droplets 1106 dispensed over the region where the depression 50a is to be deepest, and the fewest at the perimeter of the depression 50a where the depression is to be the shallowest. The stage 1114 initially moves the photoresist layer 30 under the outlet nozzle 1108 to cover the full area where the depression 50a, and thus the wedge 50, is to be formed, and sequentially smaller and smaller areas centered at the deepest locale of the to be formed depression 50a receive the etchant, and the stage eventually stops to position the drop dispensing outlet 1110 over the deepest location of the to be formed depression 50a to there dispense additional droplets 1106 of etchant, to complete etching of the photoresist layer 30 to form the wedge 50. By this methodology, the portions of the photoresist layer 30 where the shallower flank portions of the wedge 50 depression 50a are being formed will receive, and be etched by, fewer droplets of etchant, whereas the deepest areas of the depression 50a to be formed inwardly of the photoresist layer 30 receive the most droplets 1106, and there the photoresist layer 30 is recessed the deepest. The surface of the photoresist layer 30, including of the wedge 50, is then washed by deionized water, dispensed by wash nozzle 1126 to remove etched debris, etchant, quenching chemical, and any byproduct formed therein. From here, the optical device 10 will be removed from the support 1114 and positioned in a cleaning and drying station 1128 to be further cleaned and dried.

In a third aspect, etchant is released in a varying concentration or molarity across the area where the wedge 50, and thus depression 50a, is to be formed. As the etchant reacts with the underlying material of the photoresist layer 30, the etchant is consumed. To achieve deeper etching in desired regions of the photoresist layer 30 etchant droplets 1106 having a higher etchant concentration or molarity are released in areas to be deeply etched, while less concentrated droplets (diluted droplets) are released in the areas to be etched less, i.e., the shallower depression 50a areas. To achieve this, the inkjet dispenser 1104 providing etchant to the outlet nozzle 1108a is connected to two different feed lines First line 1118a contains an etchant of uniform concentration or molarity and dilutant, for example deionized water, is provided in second line 1120a. Each of the first and second lines 1118a, 1120a includes a valve 1122a, 1124a selectively opening, and capable of throttling or variable flow therethrough, the flow of the etchant (line 1118a, valve 1122a) and dilutant chemistry (line 1120a, valve 1124a) and flowing into and through the drop dispensing opening 1110a of the outlet nozzle 1108a. The relative flow of the dilutant and the etchant result in different concentrations of etchant per drop let 1006. The dispensed etchant 1116 reacts with the location of contact thereof with the photoresist layer 30 until the chemical reaction is exhausted, leaving a limited amount of etching occurring per droplet 1006, with less etching happening where droplets 1006 having lower etchant concentration were dispensed. Etchant is released in a sequentially planned fashion at a rate no quicker than the rate of consumption by the photoresist layer 30 material 12, wherein the stage 1114 moves the optical device 10 under the stream of droplets 1106. The area onto which the etchant is dispensed extends over the full area where the photoresist wedge 50, and thus depression 50a, is to be formed, with the drop dispensing outlet 1110 of the outlet nozzle 1108a releasing droplets 1106 having increasing larger ratios of etchant to dilutant from the location of the perimeter of the area of the photoresist layer 30 to be etched to the location on the photoresist layer 30 where the deepest etching into the photoresist layer 30s to occur, at which locale no dilutant with be released with etchant. Thus, the shallower flanks of the depression 50a will receive less concentrated etchant droplets 1106 whereas the deepest areas of the to be formed depression 50a in the photoresist layer 30 where the photoresist wedge 50 is being formed receive the most concentrated droplets 1106, and is therefore etched the deepest. The surface is then washed by deionized water, dispensed by rinse nozzle 1126, to remove etched debris, etchant, quenching chemical, and any byproduct formed therein. From here, the optical device 10 removed from the support 1114 and positioned in a cleaning and drying station 1128 to be cleaned and dried.

In a fourth aspect, etchant is released in different size droplets across the area of the photoresist layer 30 where the photoresist wedge 50 is to be formed. As the etchant reacts with the underlying material of the photoresist layer 30, the etchant is consumed. To achieve deeper etching into the photoresist layer 30, larger droplets are released in deep etching areas, while smaller droplets are released in the less deep wedge area. To achieve this, the inkjet printer 1100 includes an inkjet dispenser 1104 capable of dispensing smaller or larger droplets to be dropped as droplets 1106 through the drop dispensing outlet 1010 of the outlet nozzle 1108. The etchant reacts with the location of contact with the photoresist layer 30 until the chemical reaction is exhausted, leaving a limited amount of etching occurring per droplet, with less etching happening where smaller droplets 1106 were dispensed. Here, preferably a higher viscosity material as the etchant, or a carrier for the etchant, is employed, to reduce flowing of the etchant away from the location on the photoresist where it was dispensed, such that a thicker layer of etchant can be present over the deepest part of the to be formed depression tapering in thickness to the thinnest portion of etchant present at the location of the perimeter of the to be formed depression 50a. The size of the droplets 1106 is sequentially increased from the perimeter, to the deepest to be etched location, of the depression 50a to be formed. Thus, the shallower flanks of the area where the depression 50a being formed will receive smaller etchant droplets 1106 whereas the deepest areas of the depression 50a to be formed receive the largest droplets, and the photoresist layer 30 is therefore etched the deepest at that location. The surface of the photoresist layer 30 with the wedge 50 formed therein is then washed by deionized water, dispensed by wash nozzle 1126 to remove etched debris, etchant, quenching chemical, and any byproduct formed therein. From here, the optical device 10 will be removed from the support 1114 and positioned in a cleaning and drying station 1128 to be cleaned and dried.

As a result, an optical device 10 having a flat optical layer 19 with a photoresist layer 30 with a 2D wedge 50c therein can be used to form a 2D wedge 50c in the optical layer 19 thereof as shown in FIG. 5C. The photoresist layer 30 is used as a masking pattern for an anisotropic plasma etch of the device to transfer the profile of the wedge 50 into the optical layer as optical layer wedge 50b as shown in FIG. 5C. This reactive ion etch removes both the photoresist layer 30 and the optical layer 19 material, such that the wedge 50c pattern is etched into the optical layer 19 as shown in FIG. 5C. The variation in thickness created by the 2D wedge 50 in the photoresist 30 allows for more etching of the optical layer 19 to occur under the locales where there is less thickness of photoresist 30, i.e., in the deeper areas of the recess 50a, and less etching to occur in the optical layer under the more thickly covered areas thereof, i.e., in the shallower areas of the recess 50a and the non-recessed areas of the photoresist 30. The resulting etch transfers the pattern of the wedge 50 in the photoresist into the optical layer 19, resulting in an optical device 10 with a 2D optical layer wedge 50c in the optical layer 19. Any residual photoresist layer 30 is then removed by etching, and the resulting device is cleaned, such as by a wet clean process.

In FIGS. 5D and 5E, a schematic side view of a device 10 for illustrating a different series of actions to fabricate an optical device 10 with a 2D optical layer wedge 50b within the optical layer 19 of the optical device 10. This optical device 10 is not provided with a photoresist layer 30. In this aspect of the formation of the optical layer wedge 50b into the optical layer 19, any of the four aspects of the process of forming the feature as described with respect to FIGS. 5A-C are used, except the material being etched is the underlying waveguide material, and the etchant is specific to the waveguide material.

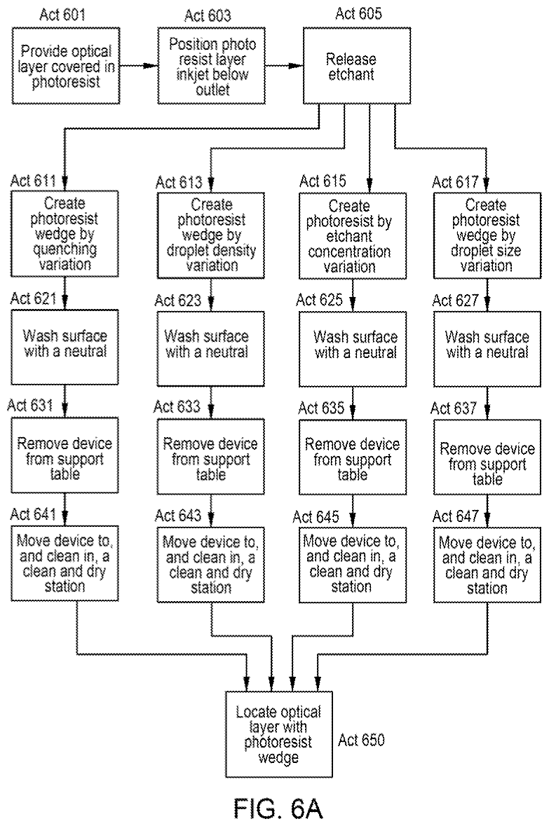

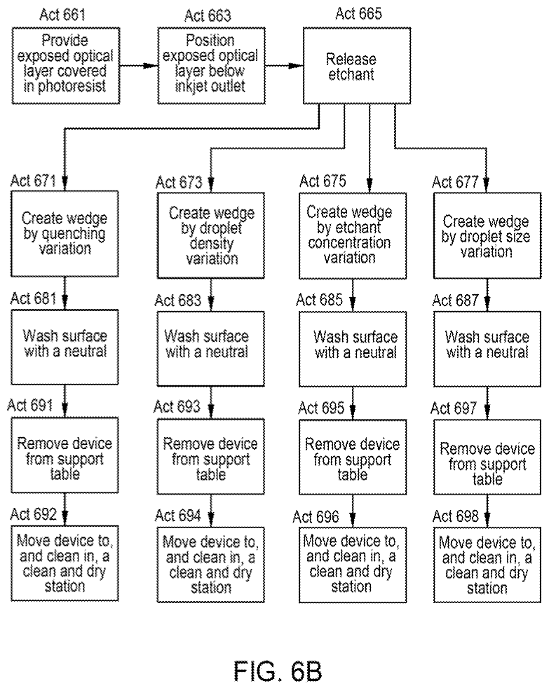

FIG. 6A is a flowchart showing a series of activities for creating a 2D optical layer wedge 50b in an optical layer 19 of an optical device 10 according to the sequence of processes described with respect to FIGS. 5A-C. Initially, an optical layer 19 coated with a photoresist layer 30 by flowable chemical vapor deposition, physical vapor deposition, spin coating or other deposition paradigm, is prepared, a wedge 50 is formed in the photoresist 30, and that wedge 50 pattern is transferred into the underlying optical layer 19.

At Act 601 the optical device 10 comprising of an optical layer 19 with a photoresist layer 30 is positioned or mounted on the stage 1114 within the inkjet wet etching device 1100, and the stage moved in the X and Θ directions of FIG. 11 to position the desired locale on the photoresist 30 where the wedge 50 is to be formed beneath the drop dispensing opening 1010 of the outlet nozzle 1008 of the inkjet printer in Act 603. At Act 605 an etchant capable of reacting with (etching) the material of the photoresist layer 30 is released from the drop dispensing opening. Specifically this etchant has an etch rate of the material of the optical layer 19 on the order of more than 100 times less than the etch rate for the photoresist layer 30 exposed to that same etchant.

The optical device 10 having the photoresist layer 30 layer thereon, is positioned on the stage 1114 to form the photoresist wedge 50 bounded by the surface of the depression 50a extending inwardly of the outer surface of the photoresist layer 30, by dispensing droplets 1106 of a wet etching or reactive chemistry onto the photoresist layer 30 from one or more outlets 1108 of an ink jet apparatus 1104. The wedge or depression 50a profile is established by causing greater etching to occur where the deepest point of the depression 50a is to be formed, and incrementally less etching to occur on the flanking side thereof, or where a circular region flanking portions radially outwardly from the deepest point of the depression 50a.

In one approach or aspect, etchant having the same etchant concentration or molarity is dropped in droplets 1106 from the injection nozzle 1108 in a uniform manner across the area where the wedge 50 is to be formed in Act 605, and a quenching chemistry is immediately thereafter released to the perimeter of the region where the wedge is being formed, and then sequentially onto additional regions of the surface of the photoresist 30, until the quenching chemistry is released over the deepest portion of the recess 50a to be formed, in Act 611. Once the surface of the photoresist layer 30 has received the quenching chemistry and the etch reaction has been quenched, at Act 621 the surface of the photoresist 30 is then washed with a neutral solution, such as by deionized water to remove etched debris, any remaining etchant, quenching chemical, and any byproduct formed therein. At Act 631 the optical device 10 with the wedge 50 formed in the photoresist 30 thereon is then removed from the stage 1114 and dried in a cleaning and drying station 1128 at Act 641 to further rinse, and then dry, the surface of the photoresist layer 30 with the 2D wedge 50c formed therein.

In a second aspect, the profile of the depression 50a is achieved by dispensing more droplets 1106 (increased density of droplets) areas of the photoresist layer 30 to be etched deeper, while fewer droplets 1106 (less droplet density) droplets 1106 having a uniform etchant concentration are released to contact on the photoresist layer 30 until the chemical reaction is exhausted, and in areas with fewer droplets, less etching will occur inwardly of the photoresist layer 30, whereas in areas of more droplet release, more etching with occur inwardly of the photoresist layer 30, the positioning of the droplets 1106 achieved by movement of the stage 1114 and consequently the photoresist layer 30 under the stream of droplets 1106 to selectively replenish the etchant at discrete locales on the photoresist layer 30. Once the depression 50a is formed, in Act 623 the surface of the photoresist layer 30, including of the wedge 50, is washed with a neutral such as deionized water to remove etched debris, etchant, quenching chemical, and any byproduct formed therein. Thereafter, the optical device 10 is removed from the support 1114 in act 633 and positioned in, and cleaned in, a cleaning and drying station 1128 in Act 643 to further rinse, and then dry, the surface of the photoresist layer 30 with the 2D wedge 50c formed therein.

In a third aspect, etchant is released in a varied concentration or molarity across the area where the depression 50a in the photoresist layer 30 is to be formed. In Act 615, droplets having a higher etchant concentration or molarity are released in areas of the photoresist layer 30 to be deeply etched, while less concentrated droplets (diluted droplets) are released in the areas to be etched less, i.e., the shallower deep wedge areas. The surface of the photoresist 30 having the depression 50a formed therein is then washed by a neutral, such as deionized water in Act 625 Then the optical device 10 is removed in Act 635 from the support 1114 and positioned in, and cleaned in, a cleaning and drying station 1128 in Act 645 to further rinse, and then dry, the surface of the photoresist layer 30 with the 2D wedge 50c formed therein.

In a fourth aspect, etchant is released in different size droplets across the area of the photoresist layer 30 where the wedge 50c is to be formed. In Act 617, larger droplets are released in deep etching areas of the depression 50a being formed, while smaller droplets (diluted droplets) are released in the shallower regions of the depression 50a being form to yield the wedge 50c, the size of the droplets 1106 modulated by the ink jet dispenser 1104 in the outlet nozzle 1108. The shallower flanks of the area where the depression 50a is being formed will receive smaller etchant droplets 1106 whereas the deepest areas of the depression 50a being formed receive the largest droplets, and the photoresist layer 30 is therefore etched the deepest at that location. In act 627 the surface of the photoresist layer 30 with the photoresist wedge 50 formed therein is then washed by deionized water to remove etched debris, etchant, quenching chemical, and any byproduct formed therein. In Act 637, the optical device 10 is removed from the support 1114 and positioned in, and cleaned in, a cleaning and drying station 1128 in Act 647 to further rinse, and then dry, the surface of the photoresist layer 30 with the 2D wedge 50c formed therein.

Thus, a resulting optical device 10 with a flat upper surface of the optical layer 19 with a photoresist layer 30 with a wedge 50 therein is formed. At this point, the shape of the wedge 50c in the photoresist layer 30 is transferred into the underlying optical layer 19, using the photoresist layer as a mask for anisotropic plasma etching of apportion of the optical layer to transfer form a corresponding wedge 50b therein in Act 650.

FIG. 6B is a flowchart showing a series of activities for creating the wedge 50b directly into the optical layer 19 of an optical device 10 according to the sequence of processes described with respect to FIG. 1. Initially, an optical layer 19 of uniform thickness is prepared.

Here, an optical device 10 having an exposed, i.e., at least a portion thereof is not covered by another film layer, is provided in Act 661, and is positioned on the stage 1114 within the inkjet wet etching device 1100, and the stage moved in the X and Θ directions of FIG. 11 to position the desired locale on the device 10 where the 2D wedge 50b is to be formed therein below the inkjet outlet nozzle 1008, in Act 663. At Act 665 an etchant capable of reacting with (etching) the material of the optical layer 19 is released from the dispense nozzle.

Here, the wedge is directly etched into the exposed surface of the optical layer 19. Examples of possible optical layer 19 layer materials and their appropriately paired etchants include the following pairs; SiO2 material and DHF etchant, Si3N4 material and HF or H3PO4 as etchant, TiO2 material and SC1 etchant, a Carbon based material and an organic solvent or a photoresist remover etchant, and an aSI (amorphous silicon) material using KOH etchant. Etching of the depression to form the optical layer 50b can be performed in a variety of different ways.

In one approach or aspect, after he substrate is provided in Act 601, and mounted on the stage 1114 and the region where the 2D wedge 50b is to be formed is positioned under the drop dispensing outlet 1110 of an outlet nozzle 1108 of an inkjet dispenser 1104 in Act 663, etchant having the same etchant concentration or molarity is dropped in droplets 1106 from the injection nozzle 1108 in a uniform manner across the area where the depression forming the optical layer wedge 50b is to be formed in Act 605. In Act 665 etchant is released to the outlet nozzle 1108a through first line 1118a to cover the entire area where the optical layer wedge 50b is to be formed, and the quenching chemistry is immediately thereafter released to the perimeter of the region where the optical layer wedge 50b is being formed in Act 671. The locations of optical layer 19 inwardly of the perimeter of the being-formed optical layer wedge 50b receive the quenching chemistry by movement of the stage 1114 to position discrete areas of the optical layer 19 under the stream of drops 1106 of the quenching chemistry at a pre-determined time at which the optical layer wedge 50b, at that location, has the desired optical layer 19 thickness. Once the entire surface of the region of the optical layer 19 where the optical layer wedge 50b is being formed has been quenched, at Act 681 the surface is then washed by a neutral, such as deionized water, dispensed by rinse nozzle 1126, to remove etched debris, any remaining etchant, quenching chemical, and any byproduct formed therein. At Act 691 the optical device 10 with wedge formed therein is then removed from the stage 1114 and positioned in a cleaning and drying station at Act 692 1128 having a spin rinse chuck 1130 to further rinse, and then dry, the surface of the photoresist layer 30 with the 2D wedge 50c formed therein.

In a second aspect, to form the optical layer wedge 50b, regions thereof to be formed requiring deeper etching, this achieved by dispensing more droplets (increased density of droplets) onto the optical layer 19 at those locations, while fewer droplets (less droplet density) are released onto the optical layer 19 in the shallower regions of the to be formed optical layer wedge 50b. In Act 673, the inkjet dispenser 1104 droplets having a uniform etchant concentration are released to contact the optical layer 19 until the chemical reaction between the droplet chemistry and the optical layer is exhausted, and in areas with fewer droplets, less etching will occur inwardly of the optical layer 19, whereas in areas of greater droplet release, more etching with occur inwardly of the optical layer 19 In Act 683 the surface of the optical layer 19, including of the just formed optical layer wedge 50b, is then washed by a neutral, such as deionized water, dispensed by wash nozzle 1126 to remove etched debris, etchant, quenching chemical, and any byproduct formed therein. Then, the optical device 10 is be removed from the support 1114 in act 693 and positioned in a cleaning and drying station 1128 in Act 694 to further rinse, and then dry, the surface of the photoresist layer 30 with the 2D wedge 50c formed therein.

In a third aspect, etchant is released in a varied concentration or molarity across the area where the optical layer wedge 50b is to be formed. In Act 675, droplets having a higher etchant concentration or molarity are released in areas of the optical layer 19 to be deeply etched, while less concentrated droplets 1106 (diluted droplets) having a lower content of the etchant or reactant therein are released in the areas to be etched less, i.e., the shallower optical layer wedge 50b areas. The surface of the optical layer 19 now including the wedge 50b is then washed by a neutral such as deionized water in Act 685, dispensed by rinse nozzle 1126, to remove etched debris, etchant, quenching chemical, and any byproduct formed therein. Then, the optical device 10 will be removed in Act 695 from the support 1114 and positioned in a cleaning and drying station 1128 in Act 696 to further rinse, and then dry, the surface of the photoresist layer 30 with the 2D wedge 50c formed therein.

In a fourth aspect, etchant droplets having different sizes and the same reactant or etchant concentration therein are released in different portions of the area of the optical layer 19 where the optical layer wedge 50b is to be formed. In Act 677, larger droplets are released in deep etching areas, while smaller droplets are released in the less deep 2D wedge 50b area, the drop size being modulated by the inkjet dispenser 1104. The shallower flanks of the area where the depression forming a wedge is being formed will receive smaller etchant droplets 1106 whereas the deepest areas of the depression being formed to create an optical layer wedge 50b receive the largest droplets, and the optical layer 19 is therefore etched the deepest at that location. In act 687 the surface of the optical layer 19 with the optical layer wedge 50b formed therein is then washed by a neutral, such as deionized water, dispensed by wash nozzle 1126 to remove etched debris, etchant, quenching chemical, and any byproduct formed therein. In Act 697, the optical device 10 is removed from the support 1114 and positioned in a cleaning and drying station 1128 in Act 698 to further rinse, and then dry, the surface of the photoresist layer 30 with the 2D wedge 50c formed therein.

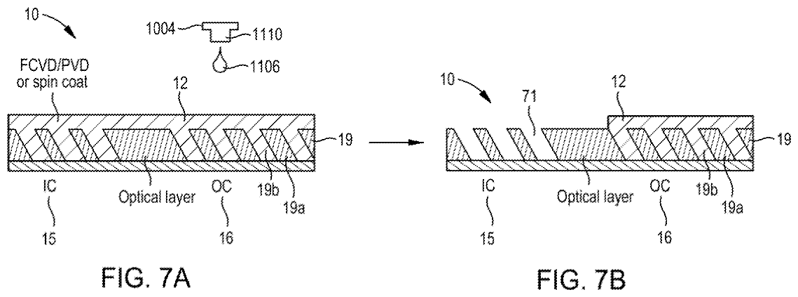

Referring to FIGS. 7A and 7B, a schematic side view of an optical device 10 with an overlying encapsulation layer 12 (FIG. 7A) portion and an open portion 71 of the encapsulation layer 12 formed by selectively removing a portion of the encapsulation layer by ink jet etching (FIG. 7B) is shown, the device 10 useful as a waveguide for use in virtual reality imaging and other applications as discussed previously herein. Here, the optical device 10 includes the open portion 71 of the encapsulation layer 12 over the incoupler 15, which open portion 71 here is formed using an inkjet dispenser 1004 to dispense an etchant to selectively, locally, remove material from the encapsulation layer 12 to locally form the open portion 71 of the encapsulation layer 12 and expose the optical layer 19 therebelow.

To form the open portion on the surface of the encapsulation layer 12, the optical device 10 having a uniform thickness encapsulation layer 12 as shown in FIG. 7A is mounted to the moveable stage 1114 of an inkjet printer 1100 of FIG. 11. To perform etching of the dielectric encapsulation layer 12 to form the opening 71 in the desired region thereof, here over the incoupler 15, stage 1114 is positioned below the drop dispensing outlet 1110 of the ink jet dispenser 1104 with the encapsulation layer 12 side of the device table facing the inkjet etching device outlet nozzle 1108, and the stage 1114 is rotated and moved in the X direction to position discrete portions of the location on the device 10 where the opening 71 is to be formed under the drop dispensing outlet 1110 of one or more inkjet dispensers 1104. The outlet 1108 nozzle facing surface of the stage 1114 is located more than the thickness of an optical device 10 from the drop dispensing opening 1010 of the outlet nozzle 1008 exit of the inkjet nozzle, leaving a distance between the nozzle exit and the surface of the encapsulation layer 12 of the optical device 10 on the order of 2 to 5 mm.

Here, as the opening 71 in the encapsulation layer exposes the underlying optical layer 19 within the perimeter thereof, the reactant or etchant to remove the encapsulation layer material should be very highly selective to etch the encapsulation layer, and the material forming the optical layer 19. Here, the in coupler 15 of the optical layer 19 has a grating of nano pillars 19a within regions 19b of the encapsulation layer 12 material extending therebetween. Thus, the portions 19b will be, or can selectively be, removed when the overlying portion of the encapsulation layer 12 is removed. Examples of possible encapsulation layer 12 layer materials and their appropriately paired etchants useful to form the opening 71 include the following pairs; SiO2 material and DHF etchant, Si3N4 material and HF or H3PO4 as etchant, TiO2 material and SC1 etchant, a Carbon based material and an organic solvent or a photoresist remover etchant, and an aSI (amorphous silicon) material using KOH etchant. Etching of the gap 71 can be done in a film layer and can be performed in a variety of different ways.

To form the opening 71, the underlying material of the optical layer 19 and the substrate 21 on which the optical layer 19 is provided serve as etch stop layers, i.e., as the etchant is selective to etch the encapsulation material highly preferentially to etching the substrate 21 and optical layer 19 materials, such that the encapsulation layer 12 over the incoupler 15 and the regions 19b therein are removed without deleterious effects on the gratings 19b or the outer surface of the optical layer 19.

To form the opening 71, etchant is dropped from the drop dispensing outlet 1010 of the inkjet dispenser 1104 uniformly over the entire region where the opening 71 is to be formed, and is allowed to etch through the encapsulation layer 12 over the incoupler 15 and also, if desired, remove the portions 19b in the incoupler 15 by continuing to allow the etchant to etch or by adding additional droplets 1106 of etchant once the surface of the optical layer 19 is exposed. Once etching is complete, here with the result shown in FIG. 7B where the portions 19b of the incoupler 15 removed, the reaction may be quenched, such as by supplying a quenching chemical through second line 1120b of FIG. 13 where the etchant was supplied through line 1120a, to be dispensed through the drop dispensing outlet 1110 of the inkjet dispenser 1104 to neutralize the etchant and thereby stop the etching, or, the surface can be rinsed with a neutral, such as deionized water dispensed from rinse nozzle 1126, to remove the etchant and stop the removal process. A quenching chemical may also be dispensed from the rinse nozzle 1126. When washed with the neutral liquid from the rinse nozzle, the liquid removes etched debris, any remaining etchant, quenching chemical, and any byproduct formed therein. The optical device 10 with gap 71 formed therein is then removed from the stage 1114 and positioned in a cleaning and drying station 1128 having a spin rinse chuck 1130 to be further cleaned and dried. Alternatively, once the opening 71 is formed but the regions 19b of the encapsulation material remain, the inkjet apparatus 1100 can be controlled to dispense droplets 1106 of etchant only onto the upper surface of the regions 19b, rather over the entire opening 71 area, to remove these regions 19b of encapsulation material.

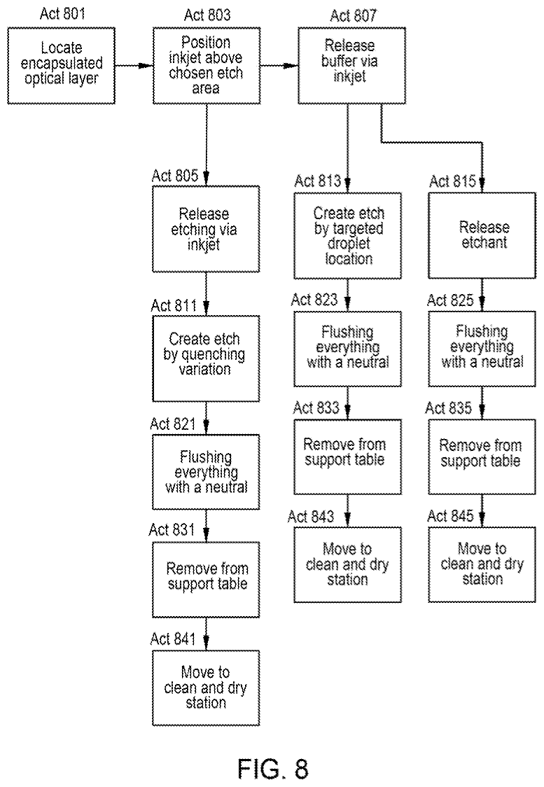

FIG. 8 is a flowchart showing a series of activities for creating the opening gap 71 in the encapsulation layer 12 over an optical layer 19 of an optical device 10 according to the sequence of processes described with respect to FIG. 7.

Initially, an optical layer 19 coated with an encapsulation layer 12 is positioned on the stage 1114, with the encapsulation layer 12 facing upwardly in Act 801. Then in Act 803, the stage 1114 is moved to position the desired location for where the opening 71 is to be formed through the encapsulation layer 12 below the drop dispensing outlet 1110 of an inkjet dispenser 1104. Thereafter, several different strategies may be taken to create the desired opening 71 in the encapsulation layer 12.

In one embodiment, etchant droplets 1106 of uniform size and etchant concentration are released over the entire surface of the encapsulation layer 12 including where the opening 71 is desired to be formed in Act 805. In Act 811 quenching chemical is released in the locations of the encapsulation layer that the etchant has reached but where the opening 71 is not desired. When opening depth is reached, i.e., when the upper layer of the optical layer 19 is exposed, etching is terminated in Act 821, such as by supplying a quenching chemistry on the exposed optical layer 19 in the opening 71 and adjacent portions of the encapsulation layer 12, supplying a rinsing liquid such as deionized water to wash away the etchant, or a combination thereof. Then, in Act 831, the device is moved to a cleaner and cleaned and dried in Act 841.

In another embodiment, etchant droplets of uniform size and etchant concentration are released exclusively at the location of the encapsulation layer 12 in which the opening 71′ is desired in Act 813. When opening depth through the encapsulation layer 12 is reached to expose the optical layer 19 therein—etching is terminated in Act 823, such as by supplying a quenching chemistry on the exposed optical layer 19 in the opening 71 and adjacent portions of the encapsulation layer 12, supplying a rinsing liquid such as deionized water to wash away the etchant, or a combination thereof. Then, in Act 833, the device is moved to a cleaner and cleaned and dried in Act 843.

In another embodiment, buffer droplets of uniform size, density, and concentration are released over the entirety of the optical device 10 except for at the location of the encapsulation layer 12 in which the opening 71′ is desired in Act 807. In Act 815 droplets having a constant concentration of the etchant therein are released over the entirety of the encapsulation layer 12, or at least portions thereof greater than the region of the opening 71 being formed. When opening depth is reached, i.e., when the optical layer 19 is exposed in the opening 71, etching is terminated in Act 825, such as by supplying a quenching chemistry on the opening 71 and adjacent portions of the encapsulation layer 12, supplying a rinsing liquid such as deionized water to wash away the etchant, or a combination thereof. Then, in Act 835, the device is moved to a cleaner and cleaned and dried in Act 845.

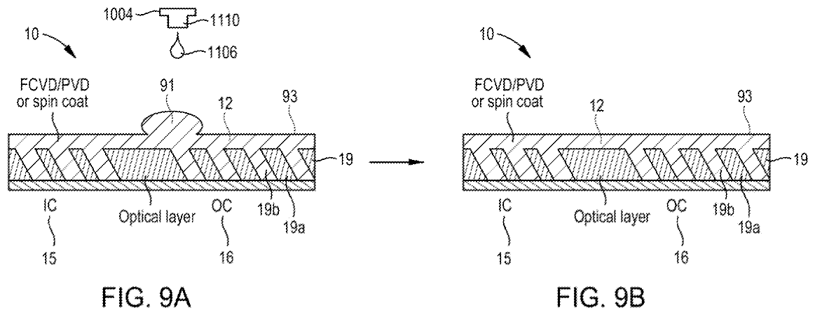

Referring to FIGS. 9A and 9B, a schematic side view of an optical device 10 with an abnormality in thickness of or in a film layer thereon, (FIG. 9A) and a smoothed abnormality in thickness of the encapsulation layer (FIG. 9B) is shown. The optical device 10 in FIG. 9A includes an abnormality in thickness 91 in the encapsulation layer 12, which here is corrected using an inkjet wet etching device 1100 to dispense an etchant to selectively, locally, remove material from the encapsulation layer to locally form the smooth and level surface of the encapsulation layer 12 of FIG. 9B.

To correct the abnormality in thickness, here an abnormality 91, or undesired extension of the encapsulation layer 12 above the desired upper plane thereof which extends on the surface of the encapsulation layer 12, the optical device 10 having the abnormality 91 is mounted to the moveable stage 1114 of an inkjet printer 1100 of FIG. 11. The printer 1100 here serves as a local, to the encapsulation layer 12 surface of the device 10, dispenser of an etchant or reactant capable of removing or etching away discrete portions of the material of the encapsulation layer 12. The printer includes the table 1102 supported on, and moveable in the X direction with respect to, a base 1112 thereof, and at least one ink jet type dispenser 1104, here four such dispensers 1104a-d, each configured to dispense droplets 1106 of liquid material therefrom, and each having an outlet nozzle 1108 which selectively faces the table 1102. The stage 1114 is rotationally coupled to the table 1102, such as through a shaft (not shown) connected to a stepper motor (not shown) in the table 1112, and the stage 114 is rotatable about its center 1116 in the 0 direction of FIG. 11. To perform etching of the dielectric encapsulation layer 12 to remove the thickness abnormality 91 in the desired region thereof, here over the thickness abnormality 91 of the device 10, stage 1114 is positioned below the outlet 1108 of the ink jet dispenser 1104 of the drop dispensing outlet 1110 of the inkjet etching device 1100 with the encapsulation layer 12 side of the device table facing the inkjet etching device outlet nozzle 1108, and the stage 1114 is rotated and moved in the X direction to position discrete portions of the location on the device 10 where the abnormality is formed and is to be removed under the outlet 1108 of one or more inkjet dispensers 1104. The outlet nozzle 1008 facing surface of the stage 1114 is located more than the thickness of an optical device 10 from the drop dispensing opening 1010 of the outlet nozzle 1008 exit of the inkjet nozzle, leaving a distance between the nozzle exit and the surface of the encapsulation layer 12 of the optical device 10 on the order of 2 to 5 mm.

To correct the abnormality in thickness 91 on the outer surface of the encapsulation layer 12 by removing the projection without leaving a significant depression in the underlying encapsulation layer 12, droplets 1106 of a wet etching or reactive chemistry are dropped onto the projection 91 from one or more outlets 1108 of an ink jet apparatus 1104. Examples of possible encapsulation layer 12 layer materials and their appropriately paired etchants include the following pairs; SiO2 material and DHF etchant, Si3N4 material and HF or H3PO4 as etchant, TiO2 material and SC1 etchant, a Carbon based material and an organic solvent or a photoresist remover etchant, and an aSI (amorphous silicon) material using KOH etchant. Etching of the 2D wedge 11 abnormality 91 can be done in a film layer and can be performed in a variety of different ways.

Here, imaging cameras 1130, 1132 of the inkjet apparatus 1100 are provided and used to locate the abnormality 91 on the encapsulation layer 12 to allow the inkjet apparatus 1100 to locate it directly below the drop dispensing outlet 1110, so that droplets of etchant which are released land on the abnormality 91, and not on the surrounding encapsulation layer 12, as well as used, in conjunction with a controller (not shown) to determine the height of the abnormality and the relative heights of different portions thereof. As the abnormality 91 is etched away by the application of the droplets 1106 of etchant, the profile of the abnormality 91, and its location, are monitored using the cameras 1130, 1132, to allow the stage 1114 to properly position the abnormality 91 under the drop dispensing outlet 1110 to ensure the droplets 1106 land on the abnormality 91 and the portions thereof extending the furthest above the otherwise flat uniform surface 93 of the encapsulation layer 12, and not on the adjacent portions of the encapsulation layer 12. Once the abnormality 91 is removed to the otherwise uniform surface 93 of the encapsulation layer as shown in FIG. 9B, etching is terminated such as rinsing the surface of the encapsulation layer 12 and the exposed portions of the optical layer 19 with a quench chemistry dispensed through the inkjet dispenser 1124 and drop dispensing opening 1110, with a neutral liquid such as deionized water dispensed through the rinse nozzle 1126, or with a quench chemistry followed by a neutral liquid wash using, for example, deionized water. Then the device is removed from the stage and mounted in a cleaning and drying station 1128 for washing and drying thereof.

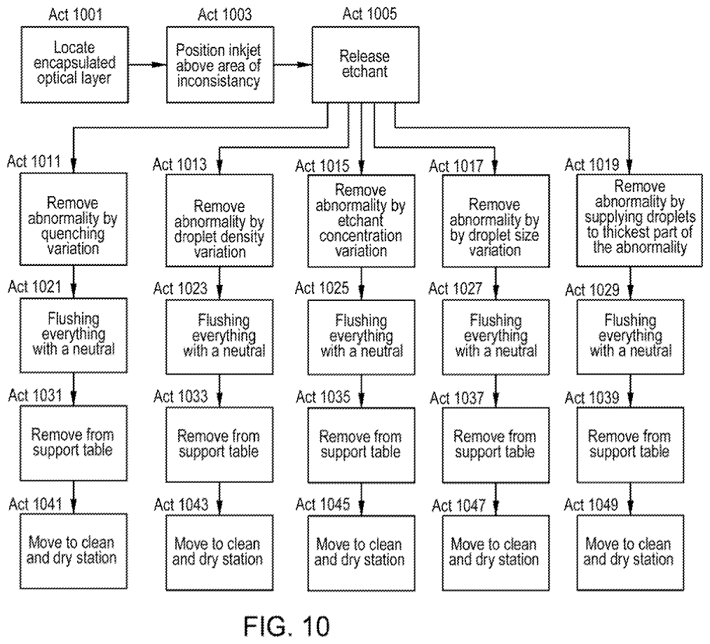

FIG. 10 is a flowchart providing a sequence of acts used to remove an abnormality 91 extending above the surface 93 of a film layer, such as an encapsulation layer 12. Initially, at Act 1001, the device 10, with the abnormality thereon, on is located on the stage 1114 of the inkjet etching apparatus 1100. Then, in Act 1003, the location of the abnormality on the encapsulation layer is established using cameras 1130, 1132, and the stage 1114 is moved to position the abnormality below a drop dispensing outlet 1110 of an inkjet dispenser 1104 in Act 1003. Then, similarly to the process for creating a 2D wedge as described in FIG. 2, at Act 1005, droplets of etchant are dispensed onto only the surface of the projection. The droplets are released utilizing the same four strategies as described in FIG. 2 as well as one new additional strategy in Act 1019. These strategies include the following; removal of the abnormality 91 by quenching variation as described in Acts 1011-1041, removal of the abnormality 91 by droplet density variation as described in Acts 1013-1043, removal of the abnormality 91 by concentration variation as described in Acts 1015-1045, and removal of the abnormality 91 by droplet size variation as described in Acts 1017-1047. These etching procedures follow the same pattern for creating more or less etching to the desired resulting architecture. In the case of creating a 2D wedge, the wedge may be etched into an already flat surface of the encapsulation layer 12, while in the case of abnormality correction, removing the abnormality 91 to yield a flat uniform surface 93 of the encapsulation layer 12 may be the desired result. Thus, here, droplets 1106 of etchant are sequentially deposited on the portions of the abnormality 91 extending furthest from the underlying desired flat, uniform, surface 93 are sequentially etched, and those locations will change as the abnormality is being removed. In Act 1019, etchant droplets of uniform size, density, and concentration are released at the most protruding point of the abnormality 91 above the desired flat uniform surface 93 of the encapsulation layer 12, which may or may not be the center of the abnormality. As etching continues, the cameras 1130 and 1132 locate where the most protruding, above the desired flat uniform surface 93 of the encapsulation layer 12, location(s) of the abnormality is, and the stage 1114 of the inkjet etching device 1100 is moved to locate the most protruding location of the abnormality 91 underneath the drop dispensing outlet 1110 of the inkjet dispenser 1104. Droplets are then dispensed again, and the sequence of locating of the most protruding portions of the abnormality, and dispensing droplets 1106 to that location, is repeated until the abnormality 91 is coplanar with the desired flat, uniform surface 93 of the encapsulation layer 12. When this planarity is reached, etching is terminated in Act 1029, such as by supplying a quenching chemistry on the abnormality 91 and adjacent portions of the encapsulation layer, supplying a rinsing liquid such as deionized water to wash away the etchant, or a combination thereof. Then, in Act 1039, the device is moved to a cleaner and cleaned and dried in Act 1049.

Referring to FIGS. 12B and 12C, a schematic side view of an optical device 10 with a uniform encapsulation layer 12 thereon, (FIG. 12B) and a 1D wedge 121 formed in the encapsulation layer 12 (FIG. 12C) is shown. The optical device 10 in FIG. 12B includes an encapsulation layer 12, in which a 1D wedge 121 here is created using an inkjet wet etching device 1100 to dispense an etchant to selectively, locally, remove material from the encapsulation layer to locally form the smooth and angled surface of the encapsulation layer 12 of FIG. 12C to form the underlying 1D wedge 121. Here, in contrast to the 2D wedge structures previously described here, where the depth of the surface feature being etched into the surface of a layer in the z direction changes in both the X and the Y directions, here, the depth of the surface feature being etched into the surface of a layer in the z direction changes in only one of the x and y directions, resulting in a ramp feature having a planar outer surface, i.e., a simple 1D wedge. As described herein, the depth of the feature is changing in only the x direction, and is constant across any Y direction thereof, the depth of the feature in adjacent Y location directions adjacent to one another in the X direction changing. This is accomplished by performing the same material removal across each Y-direction section of the feature, and increasing or decreasing the material removal at adjacent Y direction locations of the feature. As discussed herein, this can be accomplished in several ways, including applying a blanket material removal agent, i.e., an etchant, over the entire area of a surface where a wedge is to be formed, and selectively quenching the reaction across the Y direction of the surface, starting at the Xₒ end of the feature and ending at the Xₑ end of the region, wherein a plurality of n regions extend in the Y direction across the region where the feature to be formed. Here, the width of the individual regions Y₁-Yₙ in the X-direction are selected, for example, to enable discrete regions extending across the area where the 1D wedge 121 is to be formed in the Y direction having the same quench timing, or exposure of the underlying material to the etchant time period, and each adjacent region having a different quench timing, or exposure of the underlying material to the etchant time period. In FIG. 12D, region Yₒ has the fasted quench timing, in other words is quenched before any other region is quenched, the next region Y₁ has the next fasted quench timing, and each adjacent region Y₂ to Yₙ has a correspondingly longer quench timing. As a result, the depth of region Yₒ in the Z direction is less than the depth of region Y₁ in the Z direction, the depth of region Y₁ in the Z direction is less than the depth of region Y₂ in the Z direction, the depth of region Y₂ in the Z direction is less than the depth of each subsequent region Y₃ to Yₙ in the Z direction, and ultimately the depth of region Yₙ₋₁ in the Z direction is less than the depth of region Yₙ in the Z direction. Thus a feature having a sloped outer surface extending inwardly into the surface of the encapsulation layer 12 is formed. The smaller the width of each of the individual regions Y₁-Yₙ in the X direction, the smoother the transition from the depth of region Y₁ to the depth of region Yₙ, such that as the width of each Y region approaches 0 in the X-direction, the more planar the outer surface of the 1D wedge 121 becomes.

In another aspect, the 1D wedge 121 can be formed by changing the density of the droplets of etchant dispensed in the X direction, but maintaining the same density of droplets in the Y direction at each X location. As the etchant is consumed by reaction with the underlying material into which the wedge is being formed, the etch rate will fall and may reach 0 in regions were fewer droplets are dispensed, while areas where the wedge feature is etched deeper into the layer, i.e., where a greater number of droplets than adjacent, in the X direction Y regions, continue to etch inwardly of the layer, and a 1D wedge 121 as shown in FIGS. 12C and 12D can be formed. Again, the droplets 1106 can be dispensed in regions Yₒ-Yₙ in the X direction, where the number of droplets in each individual Y region is the same, but the number of droplets is different in Y regions there-adjacent in the X direction. Thus, a wedge feature having the properties of FIGS. 12C and D is formed.

In another aspect, the 1D wedge 121 is formed by changing the etchant concentration in the droplets dispensed in adjacent Y regions in the X direction, but again maintaining the etchant concentration of the droplets 1106 in each of the regions Yₒ-Yₙ constant in Y direction. Similarly, the size of the etchant droplets can be changed over the area of the to be formed wedge 121, where the etchant concentration in the droplets is the same. Hence, by depositing the smallest droplets in the entirety of region Yₒ, and sequentially increasing the droplet size in each subsequent region Yₒ-Yₙ, the wedge feature of FIGS. 12C and D can be formed.

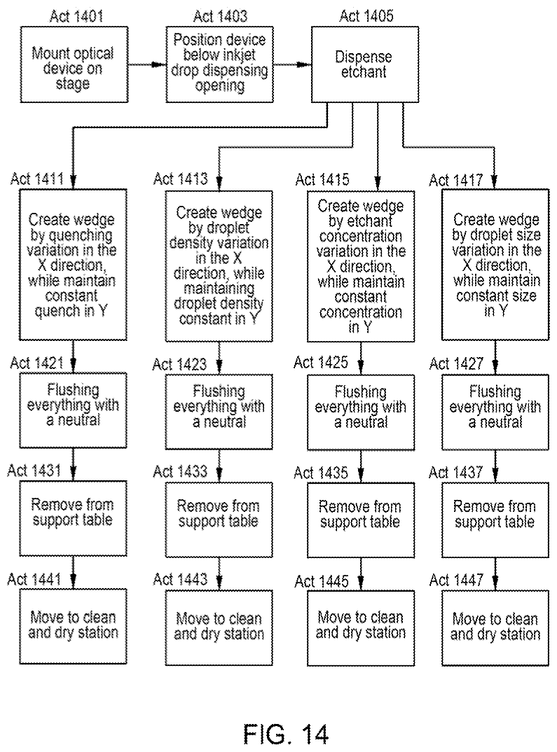

FIG. 14 is a flowchart showing a series of activities for creating a 1D wedge 121 in an encapsulation layer 12 of an optical device 10 according to the sequence of processes described with respect to FIG. 12. Initially, an optical layer 19 is prepared. However, the encapsulation layer 12 may need to have a varied thickness to create a desired effect for the optical device 10, thus the forming of a 1D wedge 121 can be performed. Herein, the process sequence for forming of the 1D wedge in the encapsulation layer 12, is described.

At Act 1301 the optical device 10 is placed on the stage 1114 of the inkjet wet etching device 1100, and in Act 1303, positioned by the stage 1114 within the inkjet wet etching device 1100, by movement in the X and Θ directions of FIG. 11, to position the desired locale on the encapsulation layer 12 where the 1D wedge is to be formed below drop dispensing opening 1110 of an outlet nozzle 1108 of an ink jet dispenser 1104. At Act 1305 an etchant capable of reacting with (etching) the material of the encapsulation layer 12 is released from the drop dispensing opening as droplets 1106. Preferably, this etchant has an etch rate of the material of the optical layer 19 on the order of more than 100 times less than the etch rate for the encapsulation layer 12 when exposed to that same etchant.

In one aspect, after etchant is released to the outlet nozzle 1108a through line 1118a to cover the entire area where the wedge profile 11a to form the wedge 121 is to be formed, a quenching chemistry is immediately thereafter released to Y₀ region of the wedge profile 11a being formed in Act 1311. The higher subscript number Y regions of the encapsulation layer of the being-formed wedge profile 11a sequentially receive the quenching chemistry thereafter by movement of the stage 1114 to position discrete areas of the encapsulation layer 12 under the stream of drops 1106 of the quenching chemistry at a pre-determined time at which the wedge profile 121a, at that location, has removed sufficient material to form the desired encapsulation layer 12 thickness of the wedge profile 11a thereat in which the amount on material removed is the same in the Y direction and varies in the X direction, to get a planar feature that extends into the layer 12 in the Z direction at a constant rate per length of X direction. Once the entire surface of the wedge profile 11a region of the encapsulation layer 12 has been quenched, At Act 1321 the surface is then washed by deionized water, dispensed by rinse nozzle 1126, to remove etched debris, any remaining etchant, quenching chemical, and any byproduct formed therein. At Act 1331 the optical device 10 with the wedge 11 formed therein is then removed from the stage 1114 and positioned in Act 1341a cleaning and drying station 1128 having a spin rinse chuck 1130 to further clean and dry the device.

In a second aspect, deeper etching is achieved by dispensing sequentially more droplets in adjacent Y regions having increasing subscript numbers in the X direction, but again maintaining the etchant droplet density constant in Y direction of the regions Yₒ-Yₙ. Hence, by depositing the smallest droplet density in the entirety of region Yₒ, and sequentially increasing the droplet density in each subsequent region Yₒ-Yₙ, the wedge feature of FIGS. 12C and D can be formed in Act 1313, by movement of the stage 1114 and consequently the encapsulation layer 12 under the stream of droplets 1106. Alternatively, where the droplets have a relatively high viscosity so as not to significantly move from their location of being dropped on the encapsulation, more droplets 1106 can be dropped in deeper locations of the wedge profile 121a to be formed than at shallower regions thereof in a single pass of the wedge profile 121a forming region of the encapsulation layer 12 under the drop dispensing outlet 1010, so that a thicker layer of etchant is present over the deeper locations of the wedge profile 11a to be formed than at shallower regions thereof. In Act 1323 the surface of the encapsulation layer 12 including the 1D wedge 121 is then washed by deionized water, dispensed by wash nozzle 1126 to remove etched debris, etchant, quenching chemical, and any byproduct formed therein. From here, the optical device 10 will be removed from the support 1114 in act 1333 and positioned in a cleaning and drying station 1128 in Act 1343 to be further cleaned and dried.

In the third aspect, in Act 1305 the etchant is released in droplets 1106 of different etchant concentration at different locations of the wedge profile 121a being formed. Droplets are dispensed in adjacent Y regions in the X direction, but again maintaining the etchant concentration of the droplets constant in Y direction of the regions Yₒ-Yₙ. Hence, by depositing the smallest droplet concentration in the entirety of region Yₒ, and sequentially increasing the droplet concentration in each subsequent region Yₒ-Yₙ, the wedge feature of FIGS. 12C and D can be formed in Act 1315. The surface of the encapsulation layer 12 including the 1D wedge 121 is then washed by deionized water in Act 1325, dispensed by rinse nozzle 1126, to remove etched debris, etchant, quenching chemical, and any byproduct formed therein. From here, the optical device 10 will be removed in Act 1335 from the support 1114 and positioned in a cleaning and drying station 1128 in Act 1345 to be further cleaned and dried.

In a fourth aspect, the etchant released in Act 1305 deeper etching is achieved by dispensing larger sized droplets in adjacent Y regions in the X direction, but again maintaining the etchant droplet size constant in Y direction of the regions Yₒ-Yₙ in Act 1317. Hence, by depositing the smallest droplet size in the entirety of region Yₒ, and sequentially increasing the droplet size in each subsequent region Yₒ-Yₙ, the wedge feature of FIGS. 12C and D can be formed. In act 1327 the surface of the encapsulation layer 12 with the 1D wedge 121 formed therein is then washed by deionized water, dispensed by wash nozzle 1126 to remove etched debris, etchant, quenching chemical, and any byproduct formed therein. In Act 1337, the optical device 10 will be removed from the support 1114 and positioned in a cleaning and drying station 1128 in Act 1347 for further cleaning and drying thereof.

In at least some embodiments hereof, surfactants are used to alter etching capabilities of the previously mentioned etching strategies. Surfactants are used to change the surface energy of the droplets. Where the surface energy of the droplet is less than the surface energy of the surface it is received on, the droplet spreads out. The higher the droplet surface energy compared to the surface energy on the surface on which it is dropped, the less the droplet spreads out. Thus, herein, one can change the local intermixing of the droplets adjacent to one another on the to-be-etched or being etched surface by selectively adding surfactant thereto, and thereby allow the droplets dispensed adjacent to each other to blend together, or stay substantially isolated from one another.

While the foregoing is directed to embodiments of the present disclosure, other and further embodiments of the disclosure may be devised without departing from the basic scope thereof, and the scope thereof is determined by the claims that follow.

What is claimed is:

1. A method of forming a three dimensional feature inwardly of a surface of a material, comprising:
providing a droplet dispenser including an outlet configured to dispense discrete droplets of a liquid material having a reactant therein capable of reacting with, and thereby removing, portions of the material layer with which the droplets come into contact;
providing a support configured support the material thereon, the support, and the droplet dispenser, movable with respect to one another, such that the outlet of the droplet dispenser is positionable over different discrete areas of the surface of the material; and
positioning the surface of the material under the droplet dispenser, and dispensing droplets to discrete portions of the surface of the material in a desired area thereof, to remove at least a portion of the material in the desired area and thereby form a three dimensional recess inwardly of the surface of the material.

2. The method of claim 1, further comprising dispensing different amounts of droplets of the liquid material to different portions of the desired area.

3. The method of claim 2, wherein, across the span of the desired area, the number of droplets dispensed is greater in regions where the 3 dimensional feature being formed is deeper.

4. The method of claim 1, wherein the droplets of liquid material dispensed from the droplet dispenser have a uniform concentration of the reactant;
the droplets of liquid are dispensed over the entire desired area, and
a quenching chemistry is applied to the desired area over a span of time, wherein portions of the desired area in which a greater amount of material is to be removed receive etchant at a later time than portions of the desired area in which a lesser amount of material s to be removed.

5. The method of claim 4, wherein the liquid droplets have the same concentration of reactant.

6. The method of claim 1, further comprising providing liquid droplets having different concentrations of the reactant therein to different discrete portions of the desired area.

7. The method of claim 6, wherein droplets having a greater concentration of the reactant therein are dispensed to discrete portions of the area where the three dimensional feature being formed is to be deeper, and droplets having a lower concentration of the reactant therein are dispensed to discrete portions of the area where the three dimension feature being formed is to be shallower than the deeper portions thereof.

8. The method of claim 1, further comprising providing liquid droplets having different volumes to different discrete portions of the desired area.

9. The method of claim 8, wherein the droplets having different volumes have the same concentration of the reactant therein.

10. The method of claim 8, wherein the droplets having a larger volume are dispensed to discrete portions of the area where the three dimensional feature being formed is to be deeper, and droplets having a lower volume are dispensed to discrete portions of the area where the three dimension feature being formed is to be shallower than the deeper portions thereof.

11. The method of claim 1, wherein the surface of the material is an abnormal feature, further comprising dispensing liquid droplets to form a three dimensional feature inwardly of the surface of the abnormal feature.

12. The method of claim 1, wherein the material is disposed over an underlying second material, and the first material is removed in the area to expose the underlying surface of the underlying second material.

13. A material layer having a three dimensional feature therein, fabricated by:
providing a droplet dispenser including an outlet configured to dispense discrete droplets of a liquid material having a reactant therein capable of reacting with, and thereby removing, portions of the material layer with which the droplets come into contact;
providing a support configured support the material thereon, the support, and the droplet dispenser, movable with respect to one another, such that the outlet of the droplet dispenser is positionable over different discrete areas of the surface of the material;
positioning the surface of the material under the droplet dispenser, and dispensing droplets to discrete portions of the surface of the material in a desired area thereof, to remove at least a portion of the material in the desired area and thereby form a three dimensional recess inwardly of the surface of the material.

14. The material layer of claim 13, further comprising dispensing different amounts of droplets of the liquid material to different portions of the desired area.

15. The material layer of claim 13, wherein the droplets of liquid material dispensed from the droplet dispenser have a uniform concentration of the reactant;
the droplets of liquid are dispensed over the entire desired area, and
a quenching chemistry is applied to the desired area over a span of time, wherein portions of the desired area in which a greater amount of material is to be removed receive etchant at a later time than portions of the desired area in which a lesser amount of material s to be removed.

16. The material layer of claim 13 further comprising providing liquid droplets having different concentrations of the reactant therein to different discrete portions of the desired area.

17. The material layer of claim 13, further comprising providing liquid droplets having different volumes to different discrete portions of the desired area.

18. A method of forming a patterned photoresist on a material layer, comprising;
providing a droplet dispenser including an outlet configured to dispense discrete droplets of a liquid material therefrom;
providing a support configured support the material layer thereon, the support, and the droplet dispenser, movable with respect to one another, such that the outlet of the droplet dispenser is positionable over different discrete areas of the surface of the material;
providing a first liquid, dispensable from the droplet dispenser in droplet form, comprising a photoresist polymer;
providing a second liquid, comprising a sensitizer which, when intermixed with the polymer, changes a reactivity of the polymer to electromagnetic energy;
positioning the surface of the material under the droplet dispenser, and dispensing droplets to discrete portions of the first liquid to the entire surface of the material layer, and dispensing droplets of the second liquid only on a desired, discrete area of the material layer to intermingle the first liquid and the second liquid in the desired, discrete area of the material layer.

19. The method of claim 18, wherein within the discrete area, different amounts of the first liquid are dispensed to different portions of the discrete area.

20. The method of claim 19, wherein multiple sublayers of the first liquid are sequentially coated onto the material layer, the first sublayer on the material layer and the subsequent sublayers formed one over the other, and, the portion of the discrete area receiving the second liquid is increased from the first sublayer to the final sublayer being formed.
